(19) United States
(12) Patent Application Publication
(10) Pub. No.: US 2025/0280575 A1
(43) Pub. Date: Sep. 4, 2025

(54) ELECTRONIC DEVICE INCLUDING A POWER TRANSISTOR INCLUDING A BURIED SHIELD AND A GAP REGION AND A PROCESS OF MAKING THE SAME

(71) Applicant: SEMICONDUCTOR COMPONENTS INDUSTRIES, LLC, Scottsdale, AZ (US)

(72) Inventor: Gary Horst LOECHELT, Tempe, AZ (US)

(73) Assignee: SEMICONDUCTOR COMPONENTS INDUSTRIES, LLC, Scottsdale, AZ (US)

(21) Appl. No.: 19/058,465

(22) Filed: Feb. 20, 2025

Related U.S. Application Data
(60) Provisional application No. 63/560,292, filed on Mar. 1, 2024.

(51) Int. Cl. H10D 62/10; H10D 30/01; H10D 30/66; H10D 62/00; H10D 62/832

(52) U.S. Cl. CPC H10D 62/109; H10D 30/0297; H10D 30/668; H10D 62/054; H10D 62/8325

(57) ABSTRACT

An electronic device can include a buried shield and a gap region. The electronic device can include a body contact region, a deep body region, or both. The deep body region can be spaced apart from the gap region and not cause R_{SP} to decrease. A combination of the body contact region and the deep body region can form a terraced conductive structure to couple the buried shield and a source terminal to each other. In an implementation, the body contact region, the deep body region, or another p-type doped region can be spaced apart from a gate member by at least a minimum distance to improve long-term reliability of a gate dielectric layer. The minimum distance can be applied as a design rule when designing the electronic device.

### CROSS REFERENCE TO RELATED APPLICATION

This application claims priority under 35 U.S.C. § 119 (c) to U.S. Patent Application No. 63/560,292 entitled “Electronic Device Including a Power Transistor,” by Gary Horst Loechelt, filed Mar. 1, 2024, which is assigned to the current assignee hereof and incorporated herein by reference in its entirety.

### FIELD OF THE DISCLOSURE

The present disclosure relates to electronic devices and processes, and more particularly, to electronic devices including power transistors that include buried shields and gap regions and processes of making the same.

### RELATED ART

Transistors can be designed to operate at relatively high voltages and high currents. Some semiconductor materials, such as monocrystalline Si, may not be able to operate at such high voltages and currents or may need complex designs to withstand the high voltages and current during operation. Wide band gap semiconductors such as SiC can be used in transistors that operate at high voltages and current. The power transistor can have a relatively high electrical field in regions near a primary surface of a substrate. Scaling transistors to smaller dimensions while maintaining an acceptable drain-to-source punchthrough voltage and maintain long-term gate dielectric reliability can be challenging. Further improvement of the power transistor is desired.

### BRIEF DESCRIPTION OF THE DRAWINGS

Implementations are illustrated by way of example and are not limited in the accompanying figures.

FIG. 1 includes an illustration of a cross-sectional view of a portion of a workpiece including a substrate that includes a semiconductor base material and a semiconductor layer.

FIG. 2 includes an illustration of a top view of the portion of the workpiece of FIG. 1 after forming mask members of a buried shield mask.

FIGS. 3 to 6 include illustrations of cross-sectional views of the workpiece of FIG. 2 after forming a buried shield and a deep portion of a source region.

FIG. 7 includes an illustration of a top view of the portion of the workpiece of FIGS. 3 to 6 after forming a deep body mask.

FIGS. 8 to 11 include illustrations of cross-sectional views of the workpiece of FIG. 7 after forming deep body regions, removing the deep body mask, and forming a carrier distribution layer and carrier accumulation region.

FIGS. 12 to 15 include illustrations of cross-sectional views of the workpiece of FIGS. 8 to 11 after forming a body region and a shallow portion of the source region.

FIG. 16 includes an illustration of a top view of the portion of the workpiece of FIGS. 12 to 15 after forming a body contact mask.

FIGS. 17 to 20 include illustrations of cross-sectional views of the workpiece of FIG. 16 after forming body contact regions and removing the body contact mask.

FIG. 21 includes an illustration of a top view of the workpiece of FIGS. 17 to 20 after forming a gate trench mask.

FIGS. 22 to 25 include illustrations of cross-sectional views of the workpiece of FIG. 21 after patterning the substrate to define gate trenches and removing the gate trench mask.

FIG. 26 includes an illustration of a top view of the workpiece of FIGS. 22 to 25 after forming a gate dielectric layer, a gate conductive layer, and mask members of a gate mask.

FIGS. 27 to 30 include illustrations of cross-sectional views of the workpiece of FIG. 26 after forming gate members and removing the mask members of the gate mask.

FIG. 31 includes an illustration of a top view of a portion of the workpiece of FIGS. 27 to 30 to illustrate minimum distances between body contact regions and gate members.

FIG. 32 includes an illustration of a perspective view of a portion of the workpiece of FIGS. 27 to 30 corresponding to a unit cell.

FIG. 33 includes an illustration of a top view of the workpiece of FIGS. 27 to 30 after forming an interlevel dielectric layer and a contact mask.

FIGS. 34 to 37 include illustrations of cross-sectional views of the workpiece of FIG. 33 after removing the contact mask and after forming a source terminal.

FIG. 38 includes an illustration of a cross-sectional view of transistor structures to illustrate majority carrier flow from the source region to the semiconductor layer via a gap region.

Skilled artisans appreciate that elements in the figures are illustrated for simplicity and clarity and have not necessarily been drawn to scale. For example, the dimensions of some of the elements in the figures may be exaggerated relative to other elements to help to improve understanding of implementations of the inventive concepts.

### DETAILED DESCRIPTION

The following description in combination with the figures is provided to assist in understanding the teachings disclosed herein. The following description will focus on specific implementations of the teachings. This focus is provided to assist in describing the teachings and should not be interpreted as a limitation on the scope or applicability of the teachings. However, other implementations can be used based on the teachings as disclosed in this application.

As used in this specification, length and width are measured in directions along or parallel to a major surface of a substrate or a semiconductor layer. Depth, height, and thickness are measured in directions perpendicular to the major surface of the substrate or the semiconductor layer.

The term “electrically coupled” is intended to mean a connection, linking, or association of two or more electronic components, circuits, systems, or any combination of: (1) at least one electronic component, (2) at least one circuit, or (3) at least one system in such a way that a signal (e.g., current, voltage, or optical signal) may be partly or completely transferred from one to another. A subset of “electrically coupled” can include an electrical connection between two electronic components. In a circuit diagram, a node corresponds to an electrical connection between the electronic components. Thus, an electrical connection is a specific type of electrical coupling; however, not all electrical couplings are electrical connections. Other types of electrical coupling include capacitive coupling, resistive coupling, and inductive coupling.

The terms “horizontal,” “lateral,” and their variants are in directions along or parallel to a major surface of a substrate or semiconductor layer, and the terms “vertical,” “height,” “depth,” and their variants are in directions perpendicular to a major surface of the substrate or the semiconductor layer. Two objects that are laterally offset can be at the same or different elevations.

The term “metal” or any of its variants is intended to refer to a material that includes an element that is within any of the Groups 1 to 12, or, within Groups 13 to 16, an element that is along or below a line defined by atomic numbers 13 (Al), 31 (Ga), 50 (Sn), 51 (Sb), and 84 (Po). Neither Si nor Ge is a metal.

The term “normal operation” and “normal operating conditions” refer to conditions under which an electronic component or device is designed to operate. The conditions may be obtained from a data sheet or other information regarding voltages, currents, capacitance, resistance, or other electrical conditions. Thus, normal operation does not include operating an electrical component or device well beyond its design limits.

The terms “overlap,” “underlap,” and their variants refer to at least portions of regions or other features that lie along a vertical line that is perpendicular to a plane defined by a major surface. Components or features that overlap or underlap each other may or may not be in physical contact with each other.

The terms “power transistor” is intended to mean a transistor that has a drain-to-source breakdown voltage (BVDS) of at least 400 V.

Unless explicitly stated to the contrary, a border between a relatively heavier doped region or layer and an immediately adjacent and relatively lighter doped region or layer of the same conductivity type is where the dopant concentration between the regions or layers is 1.1 times higher than a peak dopant concentration of the relatively lower doped region or layer.

The terms “on,” “overlying,” and “over” may be used to indicate that two or more elements are in direct physical contact with each other. However, “over” may also mean that two or more elements are not in direct contact with each other. For example, “over” may mean that one element is above another element, but the elements do not contact each other and may have another element or elements between the two elements.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is used when describing elements, components and other features described herein. This is done merely for convenience and to give a general sense of the scope of the inventive concepts. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

The use of the word “about,” “approximately,” or “substantially” is intended to mean that a value of a parameter is close to a stated value or position. However, minor differences may prevent the values or positions from being exactly as stated. Thus, differences of up to ten percent (10%) (and up to twenty percent (20%) for semiconductor doping concentrations) for the value are reasonable differences from the ideal goal of exactly as described.

Unless otherwise defined, all technical and scientific terms used herein have the same meaning as commonly understood by one of ordinary skill in the art to which these inventive concepts belong. The materials, methods, and examples are illustrative only and not intended to be limiting. To the extent not described herein, many details regarding specific materials and processing acts are conventional and may be found in textbooks and other sources within the semiconductor and electronic arts.

An electronic device can include a body contact region that is electrically coupled to a body region and a buried shield that defines a gap region. The electronic device can include a deep body region that is spaced apart from the gap region so that good on-state specific resistance, R_{SP}, can be maintained. The combination of the body contact region and the deep body region can form a terraced conducting structure.

The most common p-type dopant used in SiC is Al, whereas, the most common p-type dopant used in Si is B. The presence of Al near a gate dielectric layer may have reliability issues if too much Al migrates into the gate dielectric layer where it is near a gate member. The issues are not a concern for B. In addition to Al, the reliability issues may extend to one or more other metal elements having an atomic number of at least 13.

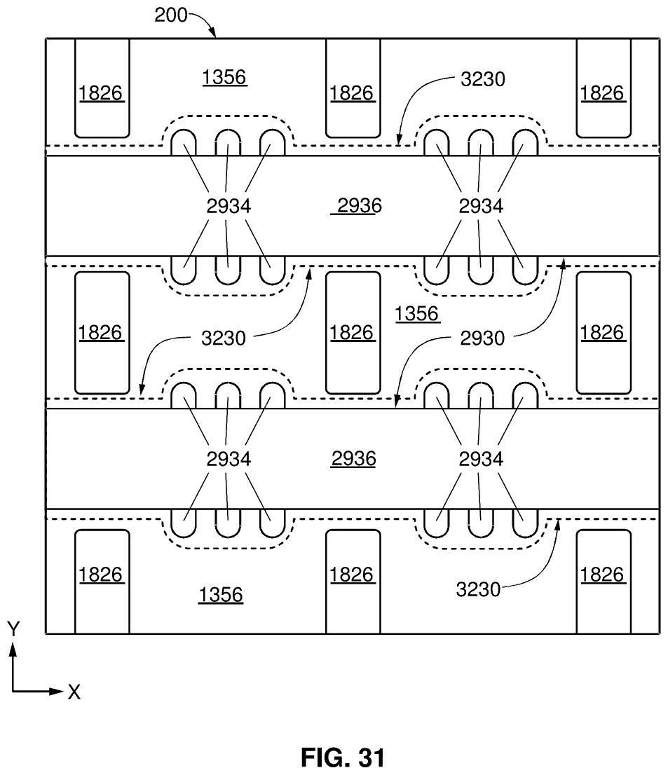

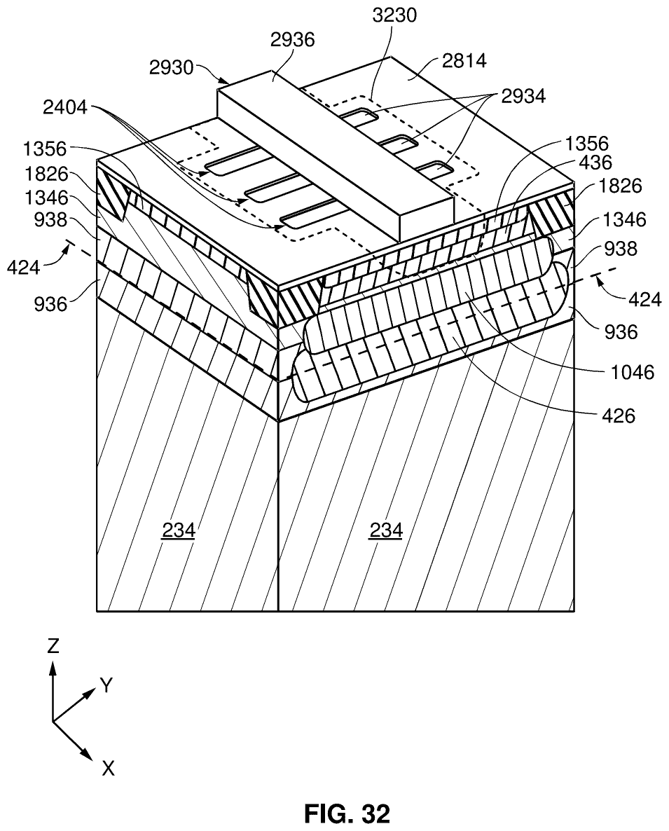

In an implementation, one or more relatively heavily doped regions may be a minimum distance from a gate member. Referring briefly to FIGS. 31 and 32, gate members 2930 can include gate electrodes 2934 and intermediate portions 2936. Dashes lines 3230 represent a minimum distance that a relatively heavily doped p-type region should be spaced apart from the gate member. FIG. 31 illustrates the minimum distance along a major surface of a substrate, and FIG. 32 illustrates the minimum distance extending from the major surface into the substrate. As will be described later in this specification, a design rule regarding the minimum distance may be triggered by a threshold dopant concentration. The minimum distance may or may not be a function of the dopant concentration. A relatively higher dopant concentration may have greater minimum distance as compared to a relatively lower dopant concentration. The concepts are better understood with respect to the drawings and description that follows.

In an aspect, an electronic device can include a substrate defining a gate trench that has a sidewall and extends to a gate trench depth from a major surface of the substrate, wherein the substrate includes a semiconductor layer having a first conductivity type; a body region having a second conductivity type opposite the first conductivity type; a body contact region having the second conductivity type; a buried shield having the second conductivity type and a peak dopant concentration, wherein the buried shield underlaps the gate trench; a deep body region having the second conductivity type and a peak dopant concentration, wherein the peak dopant concentration of the deep body region is greater than the peak dopant concentration of the buried shield; a gate dielectric layer within the gate trench; and a gate member including a portion extending into the gate trench. In a direction perpendicular to the major surface, the deep body region can be located between the body region and the buried shield, and the body region can be along a portion of the sidewall of the gate trench and is spaced apart from the gate member by the gate dielectric layer. The gate member may not overlap the body contact region, and the gate member can overlap and be spaced apart from the deep body region by the body region.

In another aspect, an electronic device can include a substrate defining a gate trench that extends to a gate trench depth from a major surface of the substrate, wherein the substrate includes a semiconductor layer having a first conductivity type; a body contact region having a second conductivity type opposite the first conductivity type; a buried shield having the second conductivity type and a peak dopant concentration, wherein the buried shield underlaps the gate trench; a gap region having the first conductivity type, wherein the gap region is defined at least in part by the buried shield; and a deep body region having the second conductivity type and a peak dopant concentration. The body contact region, the buried shield, and the deep body region are electrically coupled to one another, the deep body region may not overlap the gap region, the deep body region can be spaced apart from the major surface of the substrate, and the peak dopant concentration of the deep body region can be greater than the peak dopant concentration of the buried shield.

In a further aspect, a process of forming an electronic device can include determining a minimum distance between a gate member and a doped region within a SiC material, wherein the doped region has a dopant that is a metal element having an atomic number of at least 13, and the doped region has a peak dopant concentration of at least 5×10¹⁸ atoms/cm³. The process can further include forming a buried shield within a SiC layer of a substrate, wherein the SiC layer has a first conductivity type, and the buried shield has a second conductivity type opposite the first conductivity type; forming a body region within the SiC layer, wherein the body region has the second conductivity type, and a peak dopant concentration less than 5×10¹⁸ atoms/cm³; forming a body contact region within the SiC layer, wherein the body contact region has the second conductivity type and a peak dopant concentration of at least 5×10¹⁸ atoms/cm³, and the body contact region is electrically coupled to the buried shield; patterning the substrate defining a gate trench that has a sidewall and extends to a gate trench depth from a major surface of the substrate; and forming a gate member including a portion extending into the gate trench. The gate member can be spaced apart from the body region by a body distance that is less than the minimum distance, and the body contact region by a body contact distance that is at least the minimum distance.

In the description below, doped layers and doped regions are described with respect to dopant concentrations and depths and vertical positions (in a direction perpendicular to a major surface) and lengths and widths (along the major surface or a plane parallel to the major surface). Skilled artisans will be able to perform simulations to determine doses and energies to be used at the time of doping to achieve the doped layers and doped regions in the finished device.

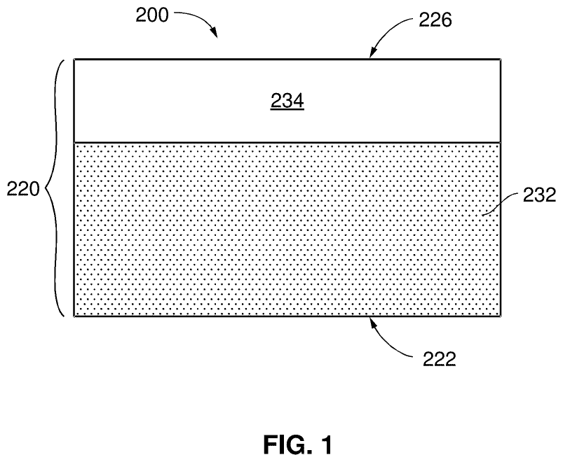

FIG. 1 includes a cross-sectional view of a portion of a workpiece 200 that includes a substrate 220 that can include a semiconductor base material 232 and a semiconductor layer 234. The semiconductor base material 232 can be a monocrystalline semiconductor wafer, a semiconductor-on-insulator (SOI) wafer, or the like. The semiconductor base material 232 and the semiconductor layer 234 can include a wide bandgap semiconductor material, and in a particular implementation, SiC is the semiconductor material within the semiconductor layer 234 and is the semiconductor material within at least the portion of the semiconductor base material 232 that contacts the semiconductor layer 234. In an implementation, the SiC can be a 3C, a 4H, or a 6H polytype.

The semiconductor material within the semiconductor base material 232 can be a drain region for the power transistor and have a dopant concentration of at least 1×10¹⁸ atoms/cm³. In a particular implementation, the dopant concentration can be at least 1×10¹⁹ atoms/cm³ to ensure an ohmic contact to a drain electrode that is subsequently attached to or formed along a back side major surface 222. The semiconductor base material 232 may have a peak dopant concentration that is at most 2×10²¹ atoms/cm³. The semiconductor material within the semiconductor base material 232 can be n-type doped or p-type doped. The majority carriers for the power transistor can be electrons, and the semiconductor material can be n-type doped. In this specification, n-type dopants can be N or P, and a p-type dopant can be Al.

The semiconductor layer 234 can be epitaxially grown and doped during or after growth. The semiconductor layer 234 can have a thickness in a range from 4.0 microns to 20.0 microns. The semiconductor layer 234 can have the same conductivity type as the semiconductor material within the semiconductor base material 232. In an implementation, the semiconductor layer 234 is n-type doped. The semiconductor layer 234 can be a drift region for the power transistor and have a lower dopant concentration as compared to the semiconductor material within the semiconductor base material 232. The average dopant concentration of the semiconductor layer 234 can be in a range from 2×10¹⁵ atoms/cm³ to 4×10¹⁶ atoms/cm³. The average dopant concentration of the semiconductor layer 234 before any further doping, such as for a body region or a source region, is referred to herein as the original dopant concentration for the semiconductor layer 234.

One or more epitaxial layers may be grown between semiconductor base material 232 and semiconductor layer 234. These additional layers may serve a number of functions including, such as, providing a transition buffer at the start of epitaxial growth, a layer for isolating crystal defects from the semiconductor layer 234, or a layer for improving stability at high current operation (i.e., safe operating area improvement). In these aforementioned cases, the additional layers usually have a higher doping concentration than semiconductor layer 234, have low resistivity because of their high doping concentration, and provide little additional benefit in blocking voltage.

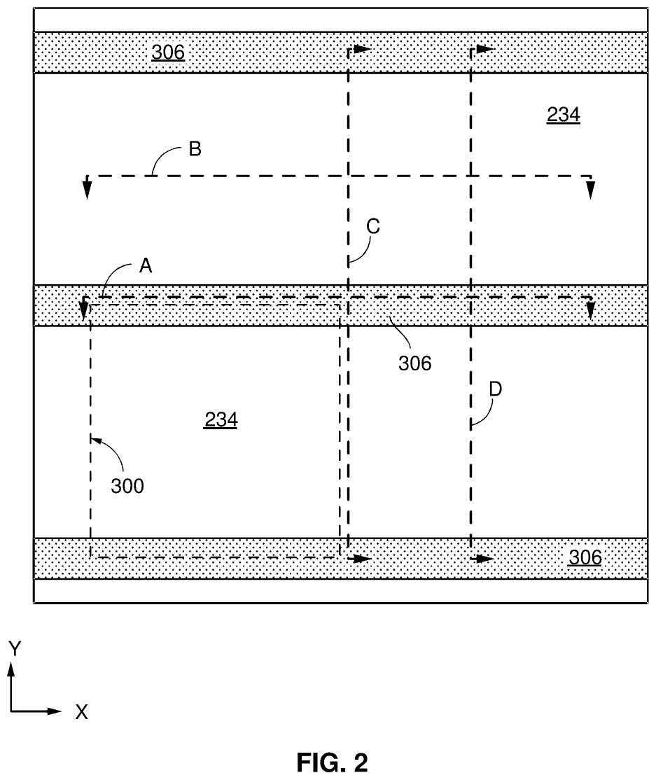

FIG. 2 includes a top view of a buried shield mask that includes mask members 306. The mask members 306 correspond to locations where gap regions will be formed. In the finished power transistor structures, electrons can flow through the gap regions when the power transistor is on. In this specification, some masks will be described as hard masks, such as the buried shield mask here. Other masks will be described as photoresist masks. In a hard mask, a pattern is first defined in photoresist and then transferred by etching to an underlying masking layer comprising either a single film or a plurality of films of oxide, nitride, polycrystalline silicon (polysilicon), or similar materials. This type of mask is referred to as a hard mask because it can withstand higher processing temperatures than photoresist, which is often needed when performing ion implantation into SiC. The need for high temperature ion implantation (for example, higher than room temperature, or 20° C. to 25° C.) increases with both the energy and dose of the implanted species. Depending upon the implant conditions, both photoresist masks and hard masks can sometimes be used interchangeably. Accordingly, the use of either a photoresist mask or a hard mask in this specification is for illustrative purposes only and should not be construed as a limitation on the invention.

The power transistor that is being formed includes many unit cells, where one of the units cells 300 is identified in FIG. 2. Many other unit cells are present but not identified in FIG. 2. The unit cells that are immediately adjacent to the right, left, above and below the unit cell 300 are mirror images of the unit cell 300. Locations not covered by the mask members 306 will be implanted to form a buried shield.

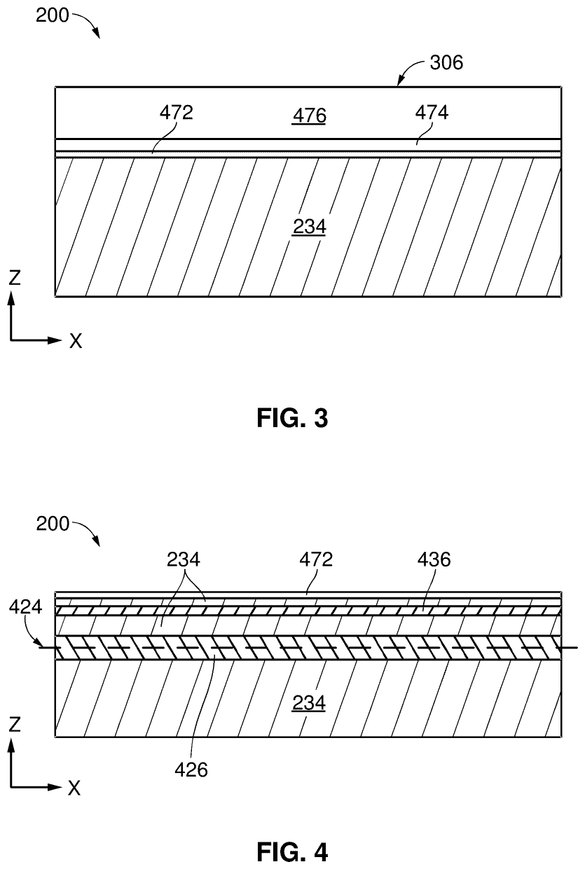

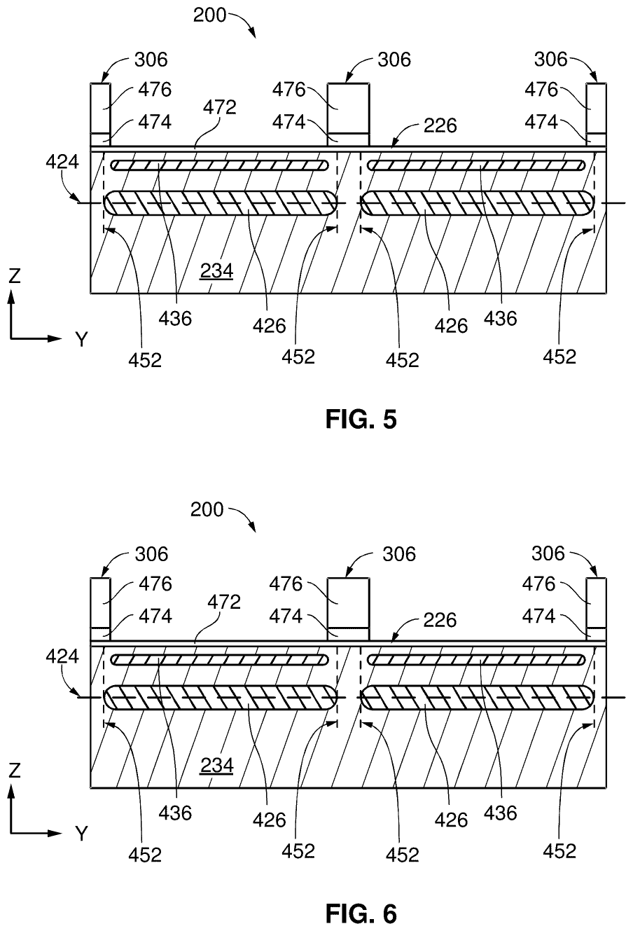

FIGS. 3 to 6 include cross-sectional views of a portion of a workpiece 200 that includes the substrate 220 after a buried shield 426 and a deep portion 436 of a source region are formed. FIG. 3 is along the sectioning line A in FIG. 2, FIG. 4 is along the sectioning line B in FIG. 2, FIG. 5 is along the sectioning line C in FIG. 2, and FIG. 6 is along the sectioning line D in FIG. 2.

In this specification, doping for each layer or region can be performed as a single ion implantation or as a plurality of ion implantations where each ion implant is performed at a different energy as compared to one or more other ion implantations within the plurality of ion implantations. After reading this specification, for each doping, skilled artisans will be able to determine the number of ion implantations, dose(s), and energy(ies) for a particular doping species (e.g., N (n-type), P (n-type), or Al (p-type)) to achieve desired doping depth(s) and a dopant concentration profile.

Referring to FIGS. 3 to 6, the buried shield mask can include a relatively thinner oxide layer 472, a polysilicon layer 474, and a relatively thicker oxide layer 476. Of the three layers, the semiconductor layer 234 is closest to the relatively thinner oxide layer 472 and farthest from the relatively thicker oxide layer 476. The relatively thinner oxide layer 472 can have a thickness in range from 10 nm to 90 nm. In the same or different implementation, the polysilicon layer 474 can have a thickness in a range from 30 nm to 300 nm. In the same or a further different implementation, the relatively thicker oxide layer 476 can have a thickness in a range from 0.9 micron to 4.0 microns. The polysilicon layer 474 and the relatively thicker oxide layer 476 can be patterned to form the mask members 306, and the relatively thinner oxide layer 472 can remain unpatterned during implantation. The relatively thinner oxide layer 472 can help to reduce the likelihood of implant channeling within the monocrystalline SiC when doping to form the buried shield 426. Also, for SiC, higher dose implants can be performed at elevated temperatures to reduce implant damage. The hard mask can allow a temperature for the ion implantation that conventional photoresist materials may not withstand.

A buried shield 426 helps to shield subsequently-formed gate electrodes from the drain voltage of the power transistor and can be used to limit or reduce the saturation current of the power transistor during a short-circuit event. The ability to survive short-circuit events on the order of several microseconds can be important for some applications such as motor drives and traction inverters. Limiting this current during a short-circuit event can extend the survival time for the power transistor. A mid-elevation line 424 is where half of a thickness of the buried shield 426 is above the mid-elevation line 424, and the other half of the thickness of buried shield 426 is below the mid-elevation line 424.

The buried shield 426 has the opposite conductivity type as compared to the semiconductor layer 234. In an implementation, the buried shield 426 can be p-type doped. The peak dopant concentration of the buried shield 426 can be the same or different from the peak dopant concentration of a subsequently-formed body region. In the same or different implementation, a peak dopant concentration of the buried shield 426 can be in a range from 8×10¹⁷ atoms/cm³ to 4.5×10¹⁸ atoms/cm³. In the same or a further implementation, the peak dopant concentration for the buried shield 426 can be at an elevation in a range from 0.3 microns to 0.9 microns below the major surface 226.

The buried shield 426 may not fully deplete during reverse bias under normal operating conditions. However, unlike the subsequently-formed body region which can influence the threshold voltage of a subsequently formed transistor, fewer electrical characteristics of the power transistor may depend upon the buried shield 426. Therefore, the buried shield 426 can have a higher dopant concentration than the subsequently-formed body region.

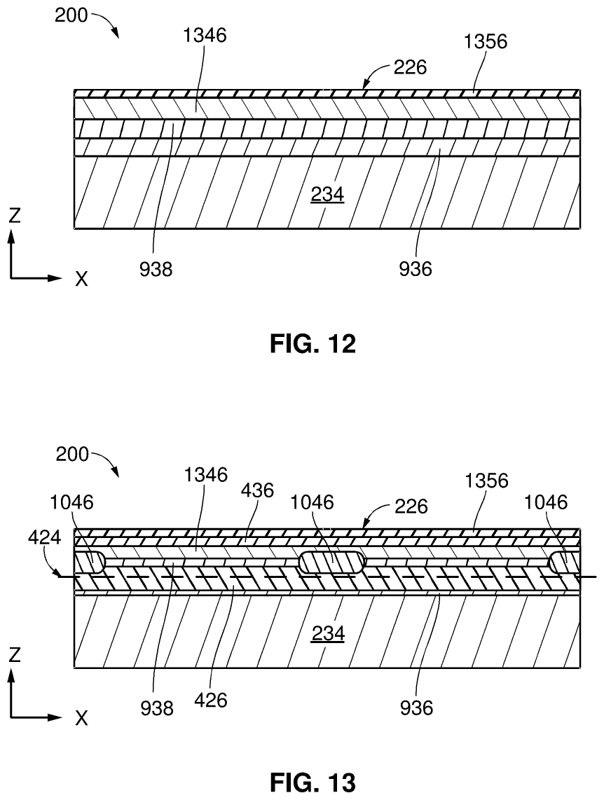

The deep portion 436 of the source region can help to keep resistance in the source region relatively low as compared to a source region that does not include the deep portion 436. A subsequently-formed shallow portion of a source region described in more detail with respect to FIGS. 12 to 15 occupies substantially all of a cell array for the power transistor. Unlike the shallow portion of the source region, the mask members 306 block the deep portion 436 from being formed across all of the cell array.

The deep portion 436 can have the same conductivity type as the semiconductor layer 234. In an implementation, the deep portion 436 can be n-type doped. The deep portion 436 can have a peak dopant concentration of at least 5×10¹⁸ atoms/cm³. In an implementation, the deep portion 436 can have a peak dopant concentration of at least 1×10¹⁹ atoms/cm³ to ensure lower resistance within the source region. In the same or different implementation, the peak dopant concentration may be at most 5×10²⁰ atoms/cm³, so that subsequently-formed body contact regions can be formed and counter dope portions of the deep portion 436. In the same or a different implementation, the deep portion 436 may extend from the major surface 226 to a depth in a range from 0.1 micron to 0.4 micron. In a particular implementation as illustrated in FIGS. 3 to 6, the deep portion 436 is spaced apart and does not contact the major surface 226.

Ion implant scattering may cause some of the dopant for each of the deep portion 436 and the buried shield 426 to extend laterally under portions of the mask members 306. As compared to the deep portion 436, the buried shield 426 can extend farther under the mask members 306 because the implant energy when forming the buried shield 426 can be greater than the implant energy when forming the deep portion 436. Thus, the buried shield 426 can underlap all of the deep portion 436.

Gap regions 452 (between the dashed lines in the figures) are regions where the conductivity type corresponds to the majority carriers for the power transistor (e.g., n-type when majority carriers are electrons, or p-type when majority carriers are holes) and are at least partly defined by the buried shield 426. The deep portion 436 of the source region does not extend into or overlap any or all of the gap regions 452. From a plan view, the gap regions 452 have shapes that correspond to the mask members 306 in FIG. 2. Each of the gap regions 452 can have a length and a width, where the length is greater than the width. The widths of the gap regions 452 are in a range from 0.4 micron to 3.0 microns, as measured in a direction that is parallel to the major surface 226 and perpendicular to a gate trench depth of subsequently-formed gate trenches. The unit cell 300 can include parts of two different gap regions 452.

In another implementation, when the buried shield mask is a hard mask, a spacer can be formed along the mask members 306 after the implantation of the buried shield 426 and before the implantation of the deep portion 436 of the source region. The spacer may be formed by depositing any of the materials described for the hard mask followed by an anisotropic etch so that a portion of the deposited film remains along a sidewall of the hard mask. When the implantation of the subsequent deep portion 436 of the source region is performed, the edge of the implanted region can be further spaced apart from gap regions 452 by a distance approximately equal to the width of the spacer along the base of the spacer. This spacer can be removed at the same time the hard mask is removed.

In still another implementation, different masks may be used to form the buried shield 426 and the deep portion 436 of the source region. The deep portion 436 may extend laterally farther from, closer to, or into the gap regions 452 as compared to the implementation as illustrated in FIGS. 3 to 6. The deep portion 436 does not extend across all of any or all of the gap regions 452. Drain-to-source breakdown voltage (BVDs) improvement may be achieved by the deep portion 436 not extending across all of any or all of the gap regions 452. Referring to FIGS. 3 to 6, from a top view, as less area is occupied by the deep portion 436, BVDs can increase to only a point, and further reduction of area occupied by the deep portion 436 does not significantly increase BVDs. However, as the area continues to be reduced, resistance attributed to the source region can increase. Thus, the area of the deep portion 436 may be reduced only to the point at which no further significant increase in BVDs occurs. After reading this specification, skilled artisans will be able to run simulations to determine an area occupied by the deep portion 436 that allows the power transistor to have acceptable values for BVDs and source resistance.

The mask members 306 and any sidewall spacers can be removed after the deep portion 436 of the source region and the buried shield 426 are formed. The relatively thinner oxide layer 472 may or may not be removed at this point in the process.

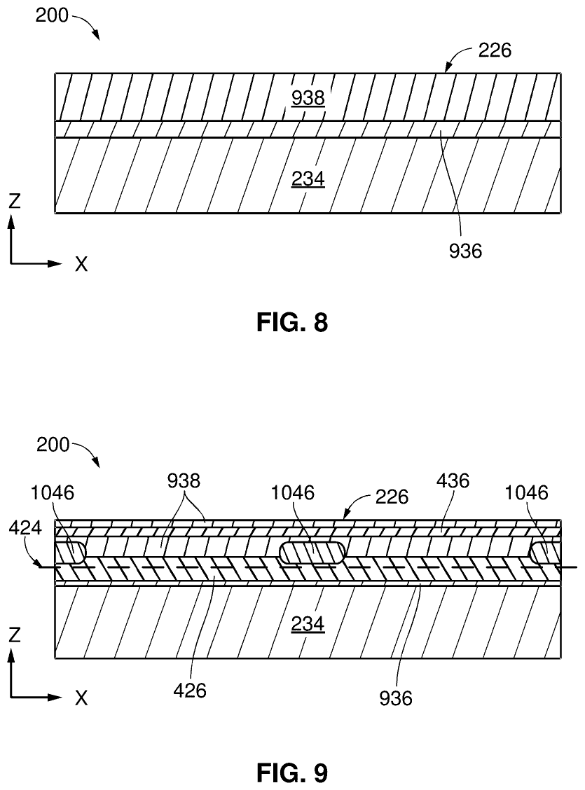

A mask (not illustrated) is formed over the workpiece 200. The active area for transistor structures of the power transistor being formed is exposed. The mask covers areas where electronic components and circuits are outside the active area for the transistor structures. The doping concentration of a surface portion of semiconductor layer 234 is enhanced to form a carrier distribution layer 936 and a carrier accumulation region 938 as illustrated in FIGS. 8 to 11.

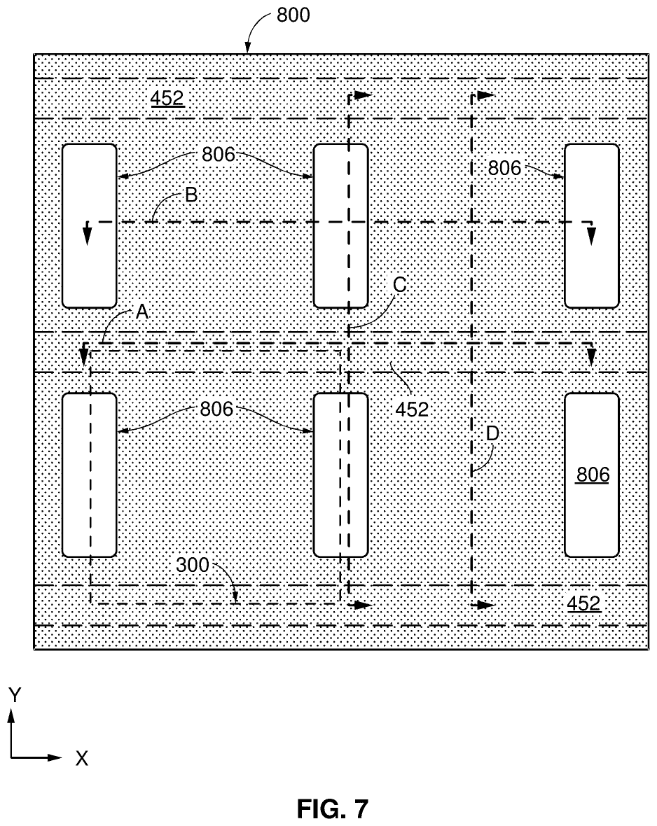

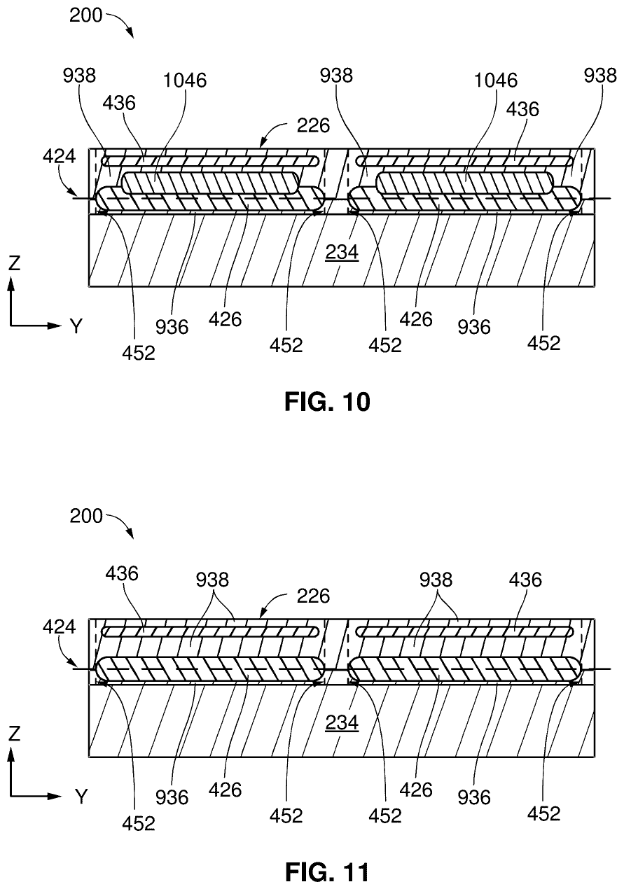

FIG. 8 is along the sectioning line A as illustrated in FIG. 7, FIG. 9 is along the sectioning line B as illustrated in FIG. 7, FIG. 10 is along the sectioning line C as illustrated in FIG. 7, and FIG. 11 is along the sectioning line D as illustrated in FIG. 7. Formation of the carrier distribution layer 936 and the carrier accumulation region 938 can be performed in either order relative to one another.

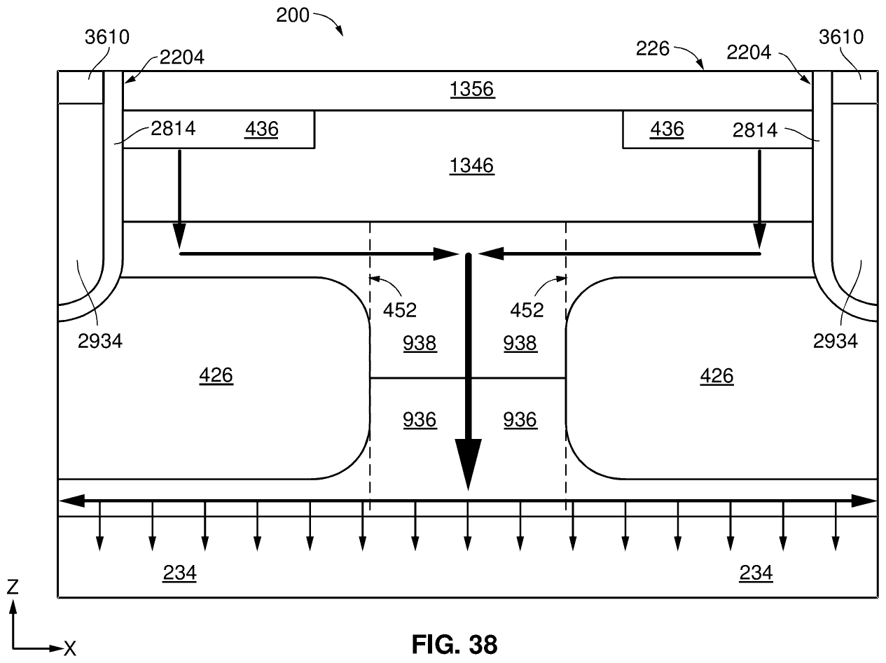

The gap regions 452 can include portions of carrier distribution layer 936 and the carrier accumulation region 938 between portions of the buried shield 426. As will be described in more detail with respect to FIG. 38, majority carriers can flow along a path through the carrier accumulation region 938, around the buried shield 426 into the gap regions 452, through the carrier distribution layer 936, and into to the semiconductor layer 234. At least a portion of the carrier distribution layer 936 may underlap the carrier accumulation region 938. In an implementation, part or all of the carrier distribution layer 936 can underlap the carrier accumulation region 938.

The border between the carrier distribution layer 936 and the carrier accumulation region 938 can be at any elevation between an uppermost elevation of the buried shield 426 and a lowermost elevation of the buried shield 426 within the unit cell 300. In a particular implementation, the border between the carrier distribution layer 936 and the carrier accumulation region 938 can be at or near the mid-elevation line 424.

On a relative basis, the peak dopant concentration of the buried shield 426 can be greater than each of the peak dopant concentrations of the carrier distribution layer 936 and the carrier accumulation region 938. The peak dopant concentration of the carrier distribution layer 936 can be the same or less than the peak dopant concentration of the carrier accumulation region 938.

The carrier accumulation region 938 can help majority carriers flow from channel regions of transistor structures of the power transistor to the gap regions 452. The carrier accumulation region 938 can be located between a subsequently-formed body region and the buried shield 426. The carrier accumulation region 938 can extend at least partly within the gap regions 452. The carrier accumulation region 938 may extend across all of the gap regions 452 within the active region of the power transistor.

In an implementation, all of the buried shield 426 underlaps a portion of the carrier accumulation region 938; however, the buried shield 426 does not underlap all of the carrier accumulation region 938. In the same or different implementation, for the array of transistor structures of the power transistor, the buried shield 426 underlaps at least 10% of the carrier accumulation region 938. As the amount of underlap increases, the ability to survive a short-circuit event improves. Thus, the underlap can be at least 40% or at least 70%. When the underlap becomes too great, R_{SP} may become higher than desired. In the same or different implementation, the buried shield 426 underlaps at most 99%, at most 98%, or at most 95% of the carrier accumulation region 938. In any of the preceding or different implementations, the buried shield 426 underlaps in a range of 70% to 95% of the carrier accumulation region 938.

The carrier accumulation region 938 can fully deplete during reverse bias under normal operating conditions. In an implementation, the carrier accumulation region 938 can fully deplete when any or all of the gap regions 452 are not fully depleted.

In a finished device, the carrier accumulation region 938 can be at an elevation that is at least 0.3 microns below the major surface 226 and may be up to 1.5 microns below the major surface 226. The carrier accumulation region 938 can have a thickness (measured in the Z-direction) in a range from 0.2 micron to 0.5 micron.

The peak dopant concentration of the carrier accumulation region 938 can be in a range from 2×10¹⁷ atoms/cm³ to 4×10¹⁸ atoms/cm³. In the same or different implementation, the carrier accumulation region 938 may have a dopant concentration gradient where a dopant concentration of the carrier accumulation region 938 at a location closer to the carrier distribution layer 936 is less than a dopant concentration of the carrier accumulation region 938 at a different location closer to the major surface 226.

The carrier distribution layer 936 can help to redistribute majority carriers along a flow path from the carrier accumulation region 938 to the semiconductor layer 234 via the gap regions 452. The carrier distribution layer 936 can extend into the gap regions 452. In an implementation, all of the buried shield 426 can overlap a portion of the carrier distribution layer 936; however, the buried shield 426 does not overlap all of the carrier distribution layer 936. In the same or different implementation, for the array of transistor structures of the power transistor, the buried shield 426 overlaps at least 10% of the carrier distribution layer 936 that lies below the mid-elevation line 424. As the amount of overlap increases, the ability to survive a short-circuit event improves. Thus, the overlap can be at least 40% or at least 70%. When the overlap becomes too great, R_{SP} may become higher than desired. In the same or different implementation, the buried shield 426 overlaps at most 99%, at most 98%, or at most 95% of the carrier distribution layer 936. In any of the preceding or different implementations, the buried shield 426 overlaps in a range of 70% to 95% of the carrier distribution layer 936.

The carrier distribution layer 936 has the same conductivity type as the semiconductor layer 234. The carrier distribution layer 936 can be n-type doped when the majority carriers are electrons. The carrier distribution layer 936 can fully deplete during reverse bias under normal operating conditions.

The carrier distribution layer 936 can have a peak dopant concentration that is greater than the average dopant concentration of the semiconductor layer 234. In an implementation, the peak dopant concentration can be less than an order of magnitude higher than the average dopant concentration of the semiconductor layer 234. The carrier distribution layer 936 can have a peak dopant concentration that is in a range from 4×10¹⁶ atoms/cm³ to 8×10¹⁷ cm³. The peak dopant concentration for the carrier distribution layer 936 can be at an elevation that is 0.7 microns to 2.0 microns below the major surface 226.

In a particular implementation, the dopant concentration for the carrier distribution layer 936 may have a dopant concentration gradient where a dopant concentration of the carrier distribution layer 936 at a location closer to the carrier accumulation region 938 is greater than a dopant concentration of the carrier distribution layer 936 at a different location closer to semiconductor base material 232.

The mask can be removed after the carrier distribution layer 936 and carrier accumulation region are formed.

FIG. 7 includes a top view of a deep body mask 800. The deep body mask 800 can be formed and define openings 806 for deep body regions. The deep body mask 800 overlaps the gap regions 452. The gap regions 452 are illustrated in FIG. 7 with dashed lines to provide a better understanding of positional relationships between the gap regions 452 and the openings 806.

The deep body mask 800 can have the same or a different composition as previously described with respect to the mask members 306 in FIG. 2. In an implementation, the deep body mask 800 can be made from an oxide layer similar to the relatively thicker oxide layer 476 previously described, and thus, the relatively thinner oxide layer 472, the polysilicon layer 474, or both may or may not be present. In a further implementation, the deep body mask 800 can be made of photoresist.

FIGS. 8 to 11 include cross-sectional views of the workpiece 200 after deep body regions 1046 are formed and the deep body mask 800 is removed. The deep body regions 1046 electrically couple the buried shield 426 and subsequently-formed body contact regions to one another. In an implementation, the deep body regions 1046 physically contact the buried shield 426. The deep body regions 1046 are spaced apart from and do not lie at the major surface 226. The deep body regions 1046 are spaced apart from and do not extend into or overlap the gap regions 452. The deep body regions 1046 can extend to any depth within the buried shield 426. In an implementation, the deep body regions 1046 can extend to a depth in a range from 0.4 micron to 0.9 micron from the major surface 226.

Each of the deep body regions 1046 can have a length and a width, where the length is greater than the width. The lengths of the deep body regions 1046 lie along lines in the Y-direction. Each of the gap regions 452 can have a length and a width, where the length is greater than the width. The lengths of the gap regions 452 lie along lines in the X-direction. The lines in the X-direction can be substantially orthogonal to the lines in the Y-direction. In an implementation, the lines in the X-direction intersect the lines in the Y-direction at an angle that is 90°+/−5°.

The deep body regions 1046 have the same conductivity type as the buried shield 426. In an implementation, the dopant for the deep body regions 1046 can include a p-type dopant that is a metal element having an atomic number of at least 13. In a particular implementation, the p-type dopant is Al. The deep body regions 1046 can have a peak dopant concentration that is greater than the peak dopant concentrations of the carrier accumulation region 938 and the buried shield 426. The peak dopant concentration of the deep body regions 1046 may or may not have a peak dopant concentration that is less than the peak dopant concentration of the deep portion 436 of the source region. In the same or a further different implementation, the deep body regions 1046 can have a peak dopant concentration of at least 5×10¹⁸ atoms/cm³ or at least 1×10¹⁹ atoms/cm³. In any of the foregoing or a different implementation, the peak dopant concentration may be at most 1×10²⁰ atoms/cm³.

A body mask (not illustrated) can be formed over the major surface 226 of the semiconductor layer 234. The active area for transistor structures of the power transistor being formed is exposed. The mask covers portions of areas where electronic components and circuits are outside the active area for the transistor structures. The body mask is used when forming a body region 1346, and a shallow portion 1356 of the source region.

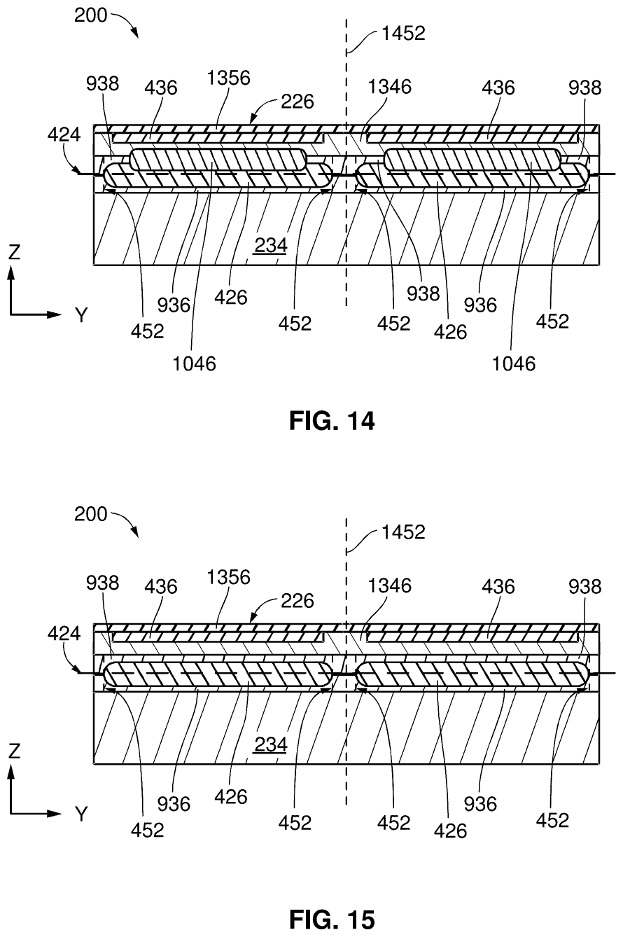

Referring to FIGS. 12 to 15, doping can be performed to form the body region 1346 and the shallow portion 1356 of the source region. FIG. 12 is along the sectioning line A as illustrated in FIG. 7, FIG. 13 is along the sectioning line B as illustrated in FIG. 7, FIG. 14 is along the sectioning line C as illustrated in FIG. 7, and FIG. 15 is along the sectioning line D as illustrated in FIG. 7. Formation of the body region 1346 and the shallow portion 1356 of the source region can be performed in either order relative to one another.

The body region 1346 includes channel regions for the transistor structures of the power transistor. The body region 1346 has a conductivity type that is opposite any one or more of the semiconductor layer 234, the carrier distribution layer 936, or the carrier accumulation region 938. In an implementation, the body region 1346 can be p-type doped. The buried shield 426 is spaced apart from the body region 1346 by at least a portion of the carrier accumulation region 938. In a direction perpendicular to the major surface 226, the body region 1346 is located between any or all of the deep body regions 1046 and the major surface 226. The body region 1346 can underlap the source region, including the shallow portion 1356 and the deep portion 436. A portion of the body region 1346 does not underlap the deep portion 436 of the source region. The body region 1346 can overlap the carrier accumulation region 938. In an implementation, the buried shield is spaced apart from the body region 1346 by the carrier accumulation region 938.

A peak dopant concentration of the body region 1346 is greater than the average dopant concentration of the semiconductor layer 234, the carrier distribution layer 936, or both. In an implementation, the peak dopant concentration is in a range from 8×10¹⁷ atoms/cm³ to 4.5×10¹⁸ atoms/cm³. A peak dopant concentration for the body region 1346 can be at an elevation that is in a range from 0.1 microns to 0.6 microns below the major surface 226. Unlike the carrier distribution layer 936 and the carrier accumulation region 938, the body region 1346 may not fully deplete during reverse bias under normal operating conditions. These depletion conditions for the carrier distribution layer 936 and the carrier accumulation region 938 can be used to determine their maximum dopant concentrations for a given device geometry, and the depletion condition for the body region 1346 can be used to determine a lower value for the dopant concentration for a given device geometry.

The source region for the power transistor can include the shallow portion 1356 and the deep portion 436. The shallow portion 1356 can have the same conductivity type as the deep portion 436 of the source region, the carrier accumulation region 938, or the carrier distribution layer 936. In an implementation, the shallow portion 1356 can be n-type doped. The shallow portion 1356 is thinner (as measured in the Z-direction) as compared to the part of the source region that includes the deep portion 436 and the shallow portion 1356.

The shallow portion 1356 can overlap the gap regions 452. The shallow portion 1356 does not extend as far into the substrate as compared to the deep portion 436. Thus, the body region 1346 is locally thicker where it overlaps the gap regions 452 and is locally thinner where it underlaps the deep portion 436 of the source region. In an implementation, a centerline 1452 can pass through a center of the narrowest widths of the gap regions 452, wherein the centerline 1452 is perpendicular to the major surface 226. The width may be measured at or near the mid-elevation line 424. The centerline 1452 can pass through the shallow portion 1356 of the source region and does not pass through the deep portion 436 of the source region. Based on simulations, the breakdown mechanism can occur by drain-to-source punchthrough at the gap regions 452 in a direction generally along or parallel to the centerline 1452 because, as compared to other regions and layers, the body region 1346 is exposed to the highest potential during reverse bias. The body region 1346 is locally thicker where it overlaps the gap regions 452 and can allow BVDs to be higher than if the deep portion 436 overlapped all of any or all of the gap regions 452.

In an implementation, the shallow portion 1356 can extend from the major surface 226 to a depth that is at most 75%, at most 65%, or at most 55% of the lowermost elevation of the deep portion 436. In the same or different implementation, the shallow portion 1356 can extend from the major surface 226 to a depth that is at least 20%, at most 25%, or at most 30% of the lowermost elevation of the deep portion 436. In either or both implementations, the shallow portion 1356 can extend from the major surface 226 to a depth that is in a range from 20% to 75%, 25% to 65%, or 30% to 55% of the lowermost elevation of the deep portion 436. The shallow portion 1356 may extend to a depth that is in a range from 0.05 micron to 0.3 micron from the major surface 226.

The peak dopant concentration of the shallow portion 1356 can be any of the peak dopant concentrations previously described with respect to the deep portion 436. In an implementation, the shallow portion 1356 and the deep portion 436 can have the same peak dopant concentration or different peak dopant concentrations.

The body mask can be removed after the body region 1346 and the shallow portion 1356 are formed.

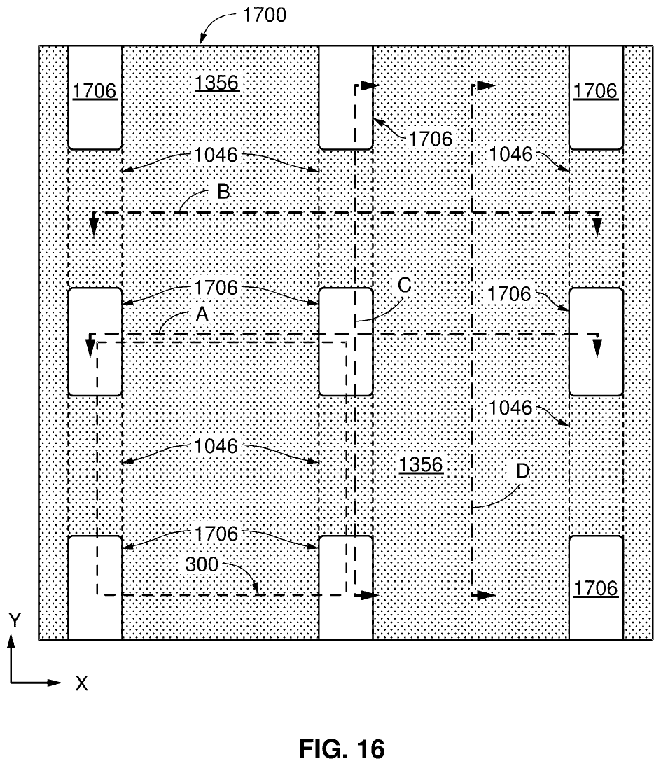

FIG. 16 includes a top view of a body contact mask 1700. The body contact mask 1700 can be formed and define openings 1706 for body contact regions. The body contact mask 1700 overlaps the shallow portion 1356 of the source region. The body contact mask 1700 can have the same or a different composition as previously described with respect to the mask members 306 in FIG. 2. In an implementation, the body contact mask 1700 can be made from an oxide layer similar to the relatively thicker oxide layer 476 previously described, and thus, the relatively thinner oxide layer 472, the polysilicon layer 474, or both may or may not be present. In a further implementation, the body contact mask 1700 can be made of photoresist.

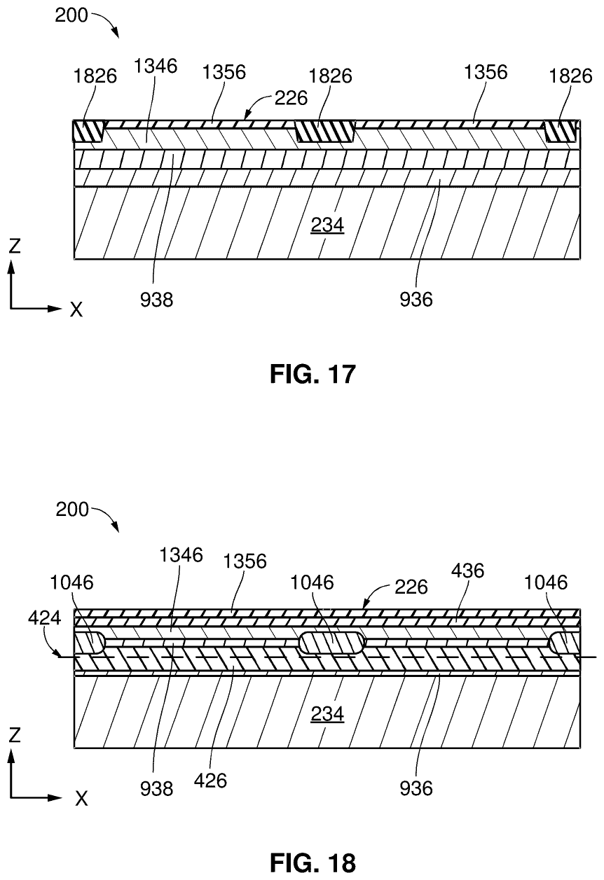

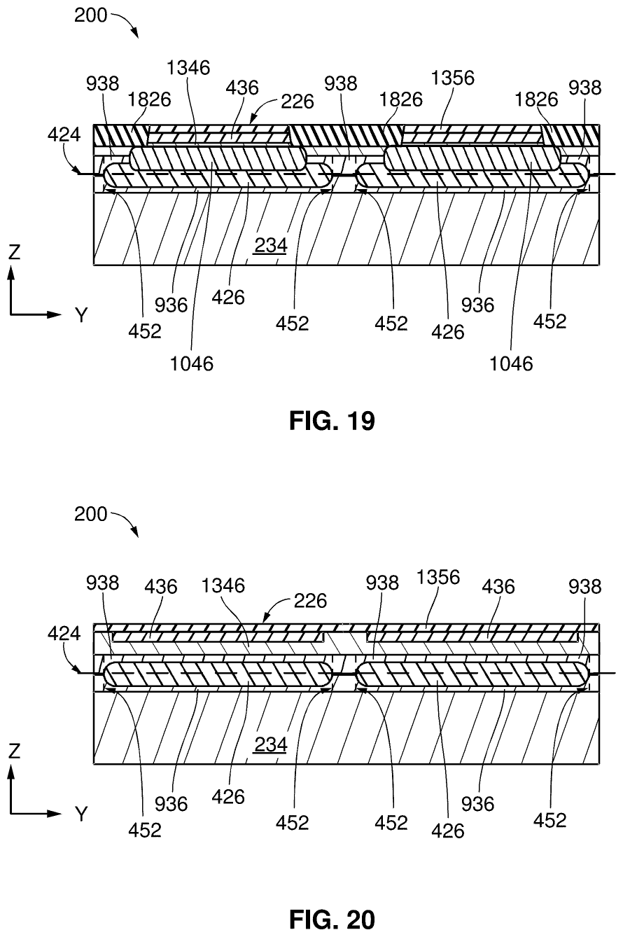

FIGS. 17 to 20 include cross-sectional views of the workpiece 200 after body contact regions 1826 are formed and the body contact mask 1700 is removed. FIG. 17 is along the sectioning line A in FIG. 16, FIG. 18 is along the sectioning line B in FIG. 16, FIG. 19 is along the sectioning line C in FIG. 16, and FIG. 20 is along the sectioning line D in FIG. 16. The body contact regions 1826 are formed below the openings 1706 of the body contact mask 1700 in FIG. 16.

The body contact regions 1826 can be electrically connected to a subsequently-formed source terminal. The deep body regions 1046 allow a resistance drop between the subsequently-formed source terminal and the buried shield 426 via the body contact regions 1826 to be less than if the deep body regions 1046 were not present. Further, the body contact regions 1826 can overlap the gap regions 452.

The body contact regions 1826, the body region 1346, the buried shield 426, and the deep body regions 1046 can be electrically coupled to one another. In an implementation, the body contact regions 1826 can be electrically connected to the body region 1346, the buried shield 426, and the deep body regions 1046. Any or all of the body contact regions 1826 may physically contact the deep body regions 1046 illustrated in FIG. 19. The body contact regions 1826 partly overlapping the deep body regions 1046 form a terraced conducting structure.

In another implementation, any or all of the deep body regions 1046 may be spaced apart from and not contact the body contact regions 1826. In an implementation, no portion of the deep body regions 1046 underlap the body contact regions 1826. If any or all of the body contact regions 1826 is spaced apart from their closest deep body regions 1046, the distance between such body contact regions 1826 and its closest deep body regions 1046 should be relatively smaller to allow for less resistance drop between the source terminal and the buried shield 426 as compared to a relatively larger distance. As used herein, a distance between first and second objects corresponds to the distance between a first point on the first object that is closest to the second object and a second point on the second object that is closest to the first object. In a particular implementation, the distance between any or all of the body contact regions 1826 and its closest deep body regions 1046 may be at most 0.5 micron, at most 0.2 micron, or at most 0.1 micron.

The body contact regions 1826 can physically contact and extend through the shallow portion 1356 and the deep portion 436 of the source region, and thus, lowermost elevations of the body contact regions 1826 can lie below a lowermost elevation of the deep portion 436 of the source region within the active region for the power transistor. At a location spaced apart from the body contact regions 1826, the shallow portion 1356 of the source region does not overlap the deep portion 436 of the source region. The body contact regions 1826 do not extend to the buried shield 426 in the implementation as illustrated in FIG. 19.

The body contact regions 1826 have the same conductivity type as the body region 1346 and the buried shield 426. In an implementation, the body contact regions 1826 can include a p-type dopant that is a metal element having an atomic number of at least 13. In a particular implementation, the p-type dopant is Al. The body contact regions 1826 can have a peak dopant concentration that is greater than the peak dopant concentration of the shallow portion 1356 and the deep portion 436 of the source region. In the same or different implementation, the peak dopant concentration of the body contact regions 1826 can be greater than the peak dopant concentration of the deep body regions 1046. The body contact regions 1826 can have a peak dopant concentration of at least 1×10¹⁹ atoms/cm³ and may have a peak dopant concentration that is at most 2×10²¹ atoms/cm³. In an implementation, the body contact regions 1826 extend from the major surface 226 to a depth in a range from 0.3 micron to 0.7 micron.

An anneal can be performed to activate dopants with respect to the previously described doping operations. Before performing the anneal, a graphite capping layer can be formed over the workpiece to protect the SiC surface from sublimation, pitting and other forms of surface roughening during the anneal. In an implementation, the graphite capping layer can have a thickness in a range from 1.5 microns to 5.0 microns. The capping layer can be deposited in the form of photoresist and decomposed to a layer primarily composed of carbon during the subsequent anneal. The anneal can be performed for a soak time in a range from 10 minutes to 60 minutes at a temperature in a range from 1500° C. to 1800° C. The dopants within the workpiece may not significantly diffuse during the anneal, and thus, the doped layers and doped regions substantially may retain their shapes and locations as originally formed. In an implementation, the anneal can be performed in an inert ambient.

The anneal can be performed before or after forming gate trenches as described below. The anneal can be performed before forming a gate dielectric layer because a material within the gate dielectric layer may not be able to withstand the temperature used for the anneal. After reading this specification, skilled artisans will be able to determine where in the process flow the anneal is performed.

Many doping operations have been described previously. The order of performing the doping operations after forming the semiconductor layer 234 can be changed. For example, doping for the body contact regions 1826 could be performed before many of the other doping operations previously described, such as doping for the carrier distribution layer 936, the carrier accumulation region 938, the body region 1346, and shallow portion 1356 and the deep portion 436 of the source region. Thus, before any anneal is performed, the doping operations can be performed in many different orders. In another implementation, another anneal may be performed after some but not all doping operations. Any doping operations performed before the other anneal is performed may not be performed after the other anneal, and any doping operations after the other anneal is performed may not be performed before the other anneal.

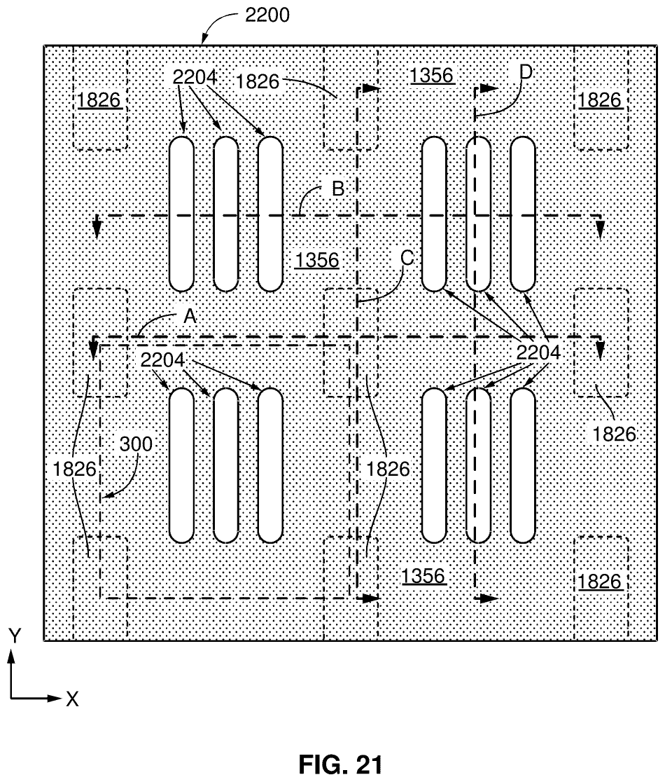

FIG. 21 includes a top view of a gate trench mask 2200 over the workpiece 200. The gate trench mask 2200 defines gate trench openings 2204 that are used to define gate trenches. The gate trench openings 2204 can be in the form of stripes that have lengths that are in the Y-direction. The gate trench mask 2200 can have the same or a different composition as previously described with respect to the buried shield mask. In an implementation, the gate trench mask 2200 can be made from an oxide layer similar to the relatively thicker oxide layer 476 previously described, and thus, the relatively thinner oxide layer 472, the polysilicon layer 474, or both may or may not be present. In another implementation, the gate trench mask 2200 can be made of photoresist.

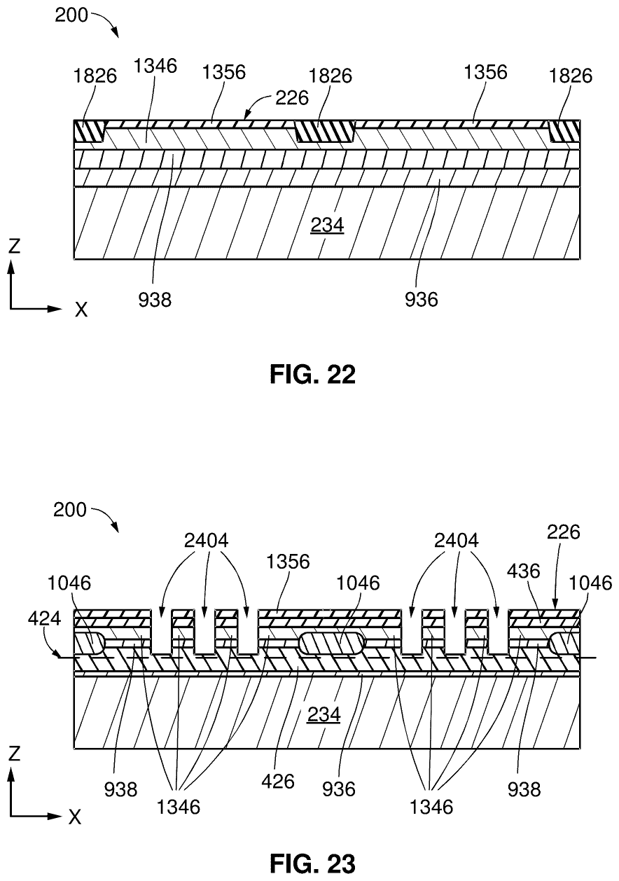

Some features are illustrated in FIG. 21 to assist in understanding the layout. The gate trench mask 2200 overlaps the portions of the shallow portion 1356 of the source region and the body contact regions 1826. The gate trench openings 2204 expose portions of the shallow portion 1356 of the source region. The body contact regions 1826 are illustrated with dashed lines. The shallow portion 1356 of the source region and the body contact regions 1826 can lie at the major surface 226 (labelled in FIGS. 22 to 25).

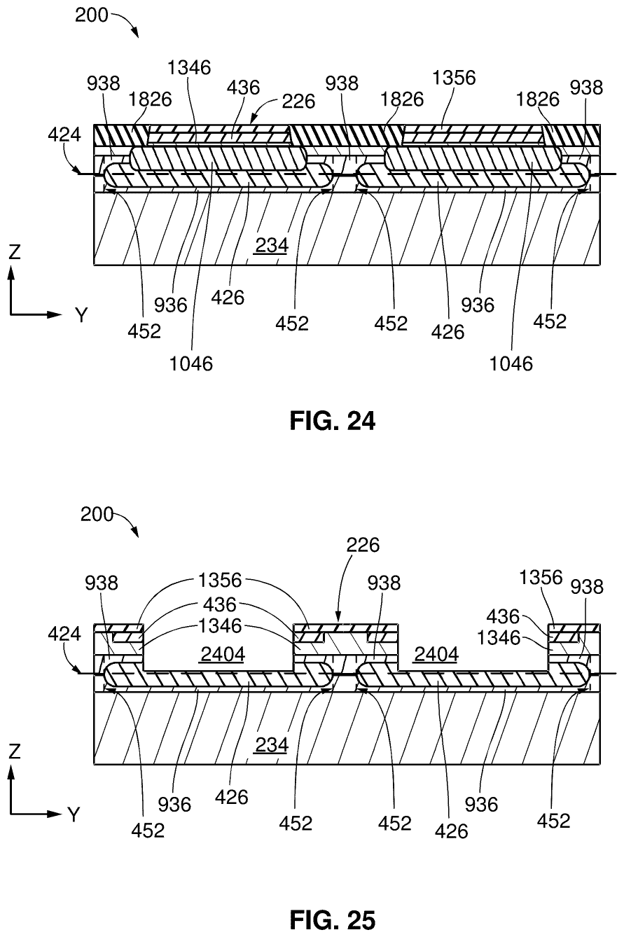

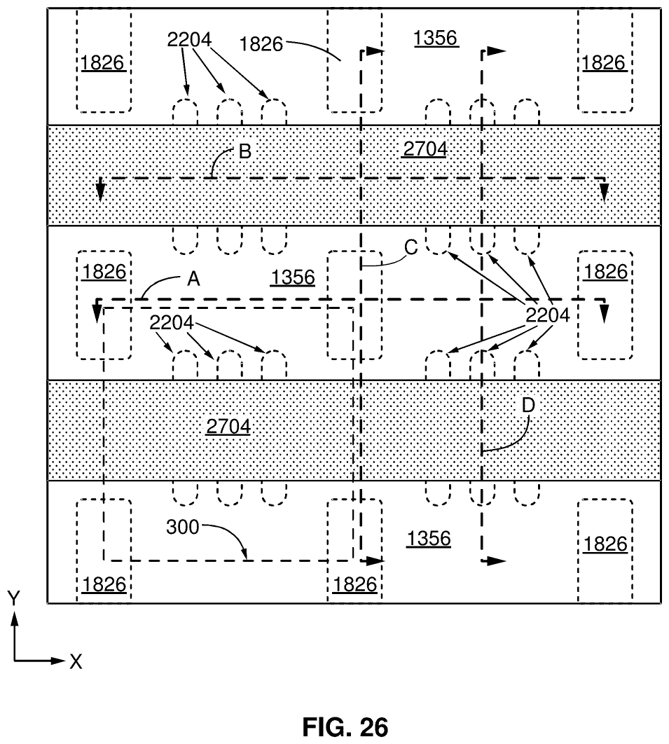

FIGS. 22 to 25 include cross-sectional views of the workpiece 200 after defining gate trenches 2404 and removing the gate trench mask 2200. FIG. 26 is along the sectioning line A in FIG. 21, FIG. 23 is along the sectioning line B in FIG. 21, FIG. 24 is along the sectioning line C in FIG. 21, and FIG. 25 is along the sectioning line D in FIG. 21.

The substrate below the gate trench openings 2204 of the gate trench mask 2200 is etched to define the gate trenches 2404 that extend to a gate trench depth from the major surface 226. Referring to FIGS. 23 and 25, the gate trenches 2404 can extend from the major surface 226 through the shallow portion 1356, the deep portion 436 of the source region, and the body region 1346 and to at least the carrier accumulation region 938. The shallow portion 1356 and the deep portion 436 of the source region, the body region 1346, and at least a portion of the carrier accumulation region 938 can lie along sidewalls of the gate trenches 2404.

In an implementation, the gate trenches 2404 can extend through the carrier accumulation region 938 and into the buried shield 426 as illustrated in FIGS. 23 and 25. Channel lengths of transistor structures of the power transistor can correspond to the thickness of the body region 1346 along the sidewalls of the gate trenches 2404. The buried shield 426 can underlap at least a portion of the body region 1346 and the gate trenches 2404. In the same or different implementation, the gate trenches 2404 do not extend completely through the buried shield 426. In the same or a more particular implementation, the gate trenches 2404 are spaced apart from and do not physically contact (1) a portion of the carrier distribution layer 936 beneath the buried shield 426, (2) the underlying semiconductor layer 234, or both (1) and (2). In any of the implementations, the depths of the gate trenches 2404 can be in a range from 0.3 micron to 1.1 microns. In another implementation, the bottoms of the gate trenches 2404 may be at an elevation as deep as 0.05 micron below the top of the carrier accumulation region 938. In any of the foregoing or a different implementation, the buried shield 426 can underlap at least a portion of the body region 1346 and the gate trenches 2404.

Widths of the gate trenches 2404 correspond to the widths of the gate trench openings 2204 that are measured in the X-direction in FIG. 21. The widths of the gate trenches 2404 can be the same or different from one another. In an implementation, the widths of the gate trenches 2404 can be in a range from 0.1 micron to 0.9 microns. The gate trench mask 2200 can be removed after the gate trenches 2404 are defined.

If the previously described anneal was not performed before defining the gate trenches 2404, the anneal can be performed after defining the gate trenches 2404. The anneal can be performed before forming the gate dielectric layer 2814. When the anneal is performed after defining the gate trenches 2404, the graphite capping layer may fill or at least partially fill the gate trenches 2404.

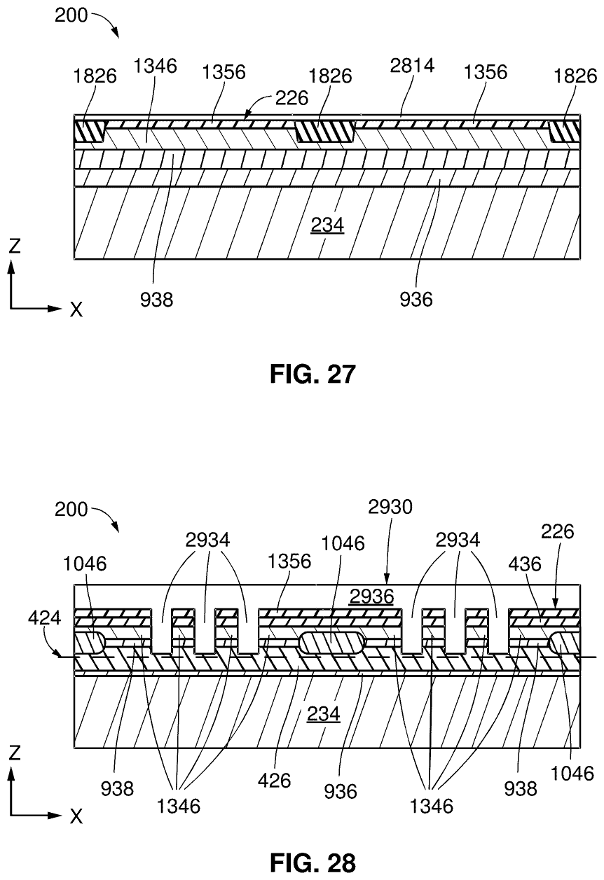

Referring briefly to FIGS. 27 to 30, a gate dielectric layer 2814 can be formed along exposed surfaces of the workpiece 200, including the sidewalls and bottoms of the gate trenches 2404 and over the shallow portion 1356 of the source region and the body contact regions 1826 that are along the major surface 226. In an implementation, the gate dielectric layer 2814 is spaced apart from and does not physically contact the gap regions 452. The gate dielectric layer 2814 can include an oxide or an oxynitride. In an implementation, the gate dielectric layer 2814 can have a thickness in a range from 20 nm to 150 nm.

After formation of the gate dielectric layer 2814, a gate conductive layer can be deposited over the gate dielectric layer 2814. The gate conductive layer can include a single film or a plurality of films, where the single film or any of the films within the plurality of films can include a doped semiconductor layer, an elemental metal (a metal that is not part of an alloy and not part of a compound, such as W, Cu, Al, etc.), a metal alloy (for example, TiW, Al-1 wt % Cu, or the like), or a conductive metal compound (for example, a conductive metal silicide or a conductive metal nitride). The gate conductive layer can have a thickness sufficient to fill the gate trenches 2404. In a particular implementation, the gate conductive layer can be n-type doped polysilicon.

FIG. 26 includes a top view of a gate mask over the workpiece 200. The gate mask is formed after the gate dielectric layer 2814 and gate conductive layer is formed. The gate mask includes gate mask members 2704 that are used to define gate members. The gate mask members 2704 can be in the form of stripes that have lengths that are in the X-direction. The gate mask can have the same or a different composition as previously described with respect to the buried shield mask. In an implementation, the gate mask members 2704 can be made from an oxide layer similar to the relatively thicker oxide layer 476 previously described, and thus, the relatively thinner oxide layer 472, the polysilicon layer 474, or both may or may not be present. In another implementation, the gate mask members 2704 can be made of photoresist.

Some features are illustrated in FIG. 26 to assist in understanding the layout. All of the workpiece illustrated in FIG. 26 is covered by the gate conductive layer, portions of which are covered by the gate mask members 2704. The gate conductive layer overlaps the shallow portion 1356 of the source region, the body contact regions 1826, and the gate trenches 2404. The shallow portion 1356 of the source region and the body contact regions 1826 can lie at the major surface 226 (labelled in FIGS. 27 to 30). The gate mask members 2704 do not overlap the gap regions 452 (not illustrated in FIG. 26) and, from a top view, are between the gap regions 452.

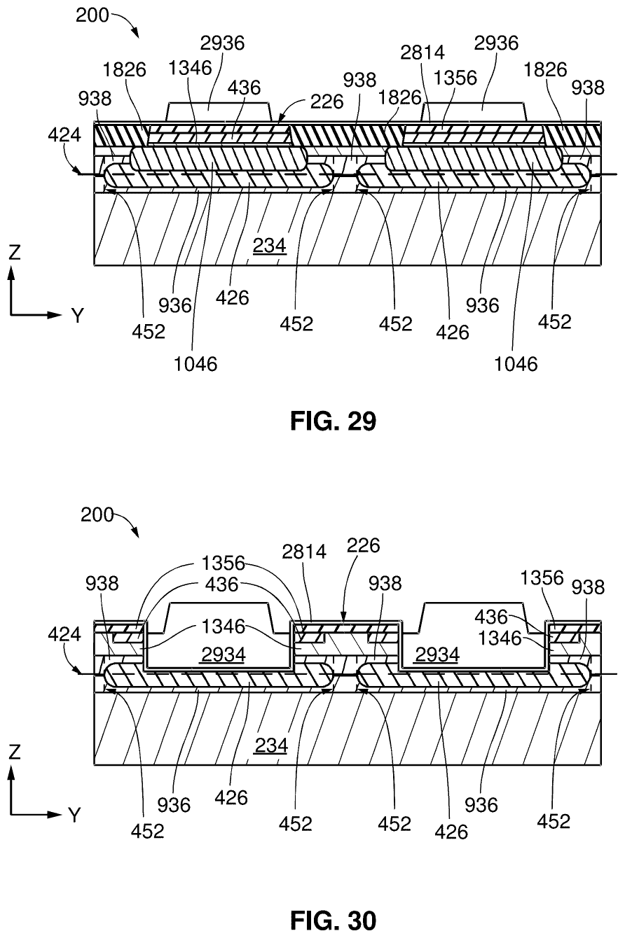

FIGS. 27 to 30 include cross-sectional views of the workpiece 200 after etching the gate conductive layer to form the gate members 2930 and removing the gate mask members 2704. FIG. 27 is along the sectioning line A in FIG. 26, FIG. 28 is along the sectioning line B in FIG. 26, FIG. 29 is along the sectioning line C in FIG. 26, and FIG. 30 is along the sectioning line D in FIG. 26.

An etch can be performed to remove portions of the gate conductive layer that overlie the gap regions 452, portions of the shallow portion 1356 of the source region, and the body contact regions 1826, all of which are outside the gate trenches, to form gate members 2930. The gate members 2930 can include gate electrodes 2934 that are portions extending into the gate trenches 2404 and intermediate portions 2936 outside of the gate trenches 2404. The etch can be performed as a timed etch or with endpoint detection and an overetch. Endpoint detection can occur when the gate dielectric layer 2814 is exposed. The overetch can be performed to recess portions of the gate electrodes 2934 within the gate trenches 2404 to reduce gate-to-source capacitance, C_{GS}. The elevation along the upper surfaces of the recessed portions of the gate electrodes are no lower than the lowermost points of the source region along their corresponding gate trenches 2404. When both the deep portion 436 and the shallow portion 1356 of the source region are present adjacent to gate trenches 2404, there is more process margin for the recessing of the gate electrodes than in a case where the deep portion 436 of the source region was not present. Since the gate electrodes should at least partially overlap the source region for good control of the threshold voltage, the presence of the deep portion 436 of the source region can improve the threshold voltage control and manufacturability of the device. In another implementation, relatively higher C_{GS} may be acceptable, and the gate electrodes 2934 may not be recessed within the gate trenches 2404.

As illustrated in FIGS. 27 to 30, the gate dielectric layer 2814 is located between the gate members 2930 and the major surface 226 and sidewalls and bottoms of the gate trenches 2404. The gate members 2930 can be spaced apart from the body region 1346 and the buried shield 426 by the gate dielectric layer 2814. The gate members 2930 can overlap any or all of the widths of the deep body regions 1046. A distance between any or all of the gate members 2930 and their closest body contact regions 1826 can be greater than the thickness of the gate dielectric layer 2814. Along a direction perpendicular to the major surface 226, the gate dielectric layer 2814, the shallow portion 1356 of the source region, and the body region 1346 are disposed between the deep body regions 1046 and the gate members 2930 overlapping such deep body regions 1046.

The gate mask members 2704 are removed after the gate conductive layer is etched to form the gate members 2930. If needed or desired, a silicide process can be performed to silicide exposed surfaces of the gate members 2930 when the gate members 2930 include doped polysilicon.

FIG. 31 includes a top view of a portion of the workpiece 200 that includes the shallow portion 1356 of the source region, the body contact regions 1826, and the gate members 2930. The gate members 2930 include the gate electrodes 2934 that extend into the gate trenches 2404 (not labeled in FIG. 31) and the intermediate portions 2936. The body contacts regions 1826 are spaced apart from the gate members 2930 by at least the minimum distance illustrated with the dashed lines 3230. The gate dielectric layer 2814 overlies the shallow portion 1356 of the source region and the body contact regions 1826 but is not illustrated in FIG. 31 to simplify understanding of the minimum distance.

Metal elements having an atomic number of at least 13, such as Al, may cause a reliability issue with respect to the gate dielectric layer 2814. Some of the metal elements may be used as p-type dopants in semiconductor materials. While many of the atoms of metal element are within the semiconductor lattice, other atoms may not be part of the lattice or break away from the lattice. During the repetitive application of a gate voltage when switching many power transistors, the metal atoms that are not within the lattice may migrate into the gate dielectric layer 2814. As more atoms of the metal element migrate into the gate dielectric layer 2814, the likelihood of a gate dielectric failure increases.

When the peak dopant concentration for a p-type region or layer is low, the risk of gate dielectric failure is less. For example, a p-type region or layer may have a dopant with a peak dopant concentration of 1×10¹⁶ atoms/cm³, and the dopant within the p-type region or layer may make up about 1 part per million of the atoms within the p-type region or layer. As the peak dopant concentration increases, so does the number of atoms of the metal element within the p-type region or layer. At a peak dopant concentration of 1×10¹⁹ atoms/cm³, the dopant may make up about 0.1% of the p-type region or layer on an atomic basis. Thus, the likelihood of a gate dielectric failure may significantly increase.

The minimum distance between a p-type doped region or layer and a gate member can be used to reduce the likelihood of a premature gate dielectric failure due to atoms of a metal element having an atomic number of at least 13 migrating into the gate dielectric layer 2814. When the minimum distance becomes too large, the unit cells can become larger, which is undesired. In an implementation, the minimum distance may be at most 0.9 micron, at most 0.7 micron, or at most 0.5 micron. The minimum distance may be at least 0.1 micron. Other values for the minimum distance may be greater or lower than those listed. The minimum distance can be greater than the thickness of the gate dielectric layer 2814.

The minimum distance may be a fixed value or a value that is a function of peak dopant concentration. Regarding a fixed value, the minimum distance may be used when the peak dopant concentration is at or greater than a threshold value. For example, if the peak dopant concentration is less than the threshold value, there may be no design rule that uses the minimum distance. At or greater than the threshold value (for example, a peak dopant concentration of 5×10¹⁸ atoms/cm³) the minimum distance is 0.4 micron. In another implementation, the minimum distance can be a function of dopant concentration and increase with increasing peak dopant concentration. For example, the minimum distance can be 0.2 micron when the peak dopant concentration is 1×10¹⁹ atoms/cm³, 0.3 micron when the peak dopant concentration is 1×10²⁰ atoms/cm³, and 0.4 micron when the peak dopant concentration is 1×10²¹ atoms/cm³.

In a further implementation, the minimum distance may include a first value corresponding to a threshold value for the peak dopant concentration and an additional value for increasing peak dopant concentration. As a non-limiting example, the threshold value for the peak dopant concentration may be 5×10¹⁸ atoms/cm³. Below that value, there is no minimum distance, or it is set to 0. At or above 5×10¹⁸ atoms/cm³, the minimum distance can be based on a calculated value in Equation 1 below.

$${D}_{calc} = ( log ( value of P D C ) - log ( 1 \times {10}^{18} ) ) \times 0.15 micron , \\ where \qquad ( Equation 1 )$$

D_{calc} is the calculated distance, and
value of PDC is the peak dopant concentration excluding the units (atoms/cm³).

When the peak dopant concentration is 1×10²⁰ atoms/cm³,

$${D}_{calc} = ( log ( 1 \times {10}^{20} ) - log ( 1 \times {10}^{18} ) ) \times 0.15 micron = ( 20 - 18 ) \times 0.15 = 0.3 micron .$$

A different equation may be used for the calculated distance. After reading this specification, skilled artisans will be able to determine an equation that meets the needs or desires for a particular application.

In practice, the minimum distance may not be exactly the calculated distance due to variation that occurs in manufacturing. Thus, the minimum distance may be +/−10% of the calculated distance. In the example above, the minimum distance can be in a range from 0.27 micron to 0.33 micron.

The previous description is based on a minimum distance that is the same in all directions. Alternatively, the minimum distance may have a horizontal component in a direction along the major surface and a vertical component in a direction perpendicular to the major surface. The horizontal component may be the same or different from the vertical component. For example, a common variation in manufacturing is the misalignment of photo mask layers. In this case, it might be more appropriate to add a fixed misalignment number to the value previously calculated. For instance, suppose the misalignment tolerance between two mask layers is 0.20 micron. Then, in the example above, the horizontal component of the minimum distance could be increased to 0.50 micron (or 0.45 micron to 0.55 micron to allow some manufacturing tolerance) to accommodate a worst-case mask misalignment. When taking mask misalignment into account, it is also possible to have a different minimum distance for horizontal spacing as opposed to vertical spacing, since the horizontal spacing could be affected by mask misalignment whereas the vertical spacing could be affected by variations in the depth of ion implantation and not be affected by photo mask misalignment. Thus, the vertical component of the minimum distance may remain at 0.3 micron (or 0.27 micron to 0.33 micron to allow some manufacturing tolerance).

The minimum distance may be implemented as a design rule when designing the power transistor. The design must still comply with other design rules. For example, the body region 1346 may have a peak dopant concentration that is less than the threshold value to trigger the minimum distance. Within the unit cell 300, the distance between the body region 1346 and the gate electrodes 2934 is not zero because the transistor would not operate properly if the body region 1346 is electrically shorted to any of the gate electrodes 2934. Thus, even though the peak dopant concentration of the body region 1346 does not trigger the minimum distance rule or would be assigned a value of 0 micron, another design rule requires the gate dielectric layer 2814 of an appropriate thickness to be located between the body region 1346 and the gate electrodes 2934.

A process of forming an electronic device can include implementing the design rule when simulating and making masks for the electronic device. The process can include determining a minimum distance between a gate member and a doped region within a SiC material. The doped region has a dopant that is a metal element having an atomic number of at least 13, and the doped region has a peak dopant concentration of at least 5×10¹⁸ atoms/cm³. A body contact region, a deep body region, or another p-type doped region or layer can be formed such that it is spaced apart from a gate member by a distance that is at least the minimum distance.

Much of the description herein has SiC as a semiconductor base material and Al as a p-type dopant. The minimum distance may be applicable to compound semiconductor base materials, such as SiC, SiGe, III-V semiconductor materials, and II-VI semiconductor materials, and to other p-type dopants that are metal elements having an atomic number greater than Al (13).

The minimum distance can extend in all directions and not be limited only to the X-Y plane. The minimum distance can extend into the substrate (Z-direction). FIG. 32 further includes a perspective view of a portion of the workpiece 200 at this point in the process. The view in FIG. 32 can correspond to the unit cell 300. The gate dielectric layer 2814 lies along the major surface 226 of the workpiece 200 and sidewalls of the gate trenches 2404. The deep body regions 1046 are spaced apart from the gate members 2930 by at least the minimum distance (dashed lines 3230). The gate member 2930 in FIG. 32 includes gate electrodes 2934 within the gate trenches 2404 and intermediate portions 2936 outside of the gate trenches 2404. Parts of body contact regions 1826 are in the corners. One of the deep body regions 1046 is seen along its length on the right front face of the illustration. Parts of the shallow portion 1356 and the deep portion 436 of the source region overlaps the deep body regions 1046. The deep portion 436 of the source region does not overlap the gap regions 452.

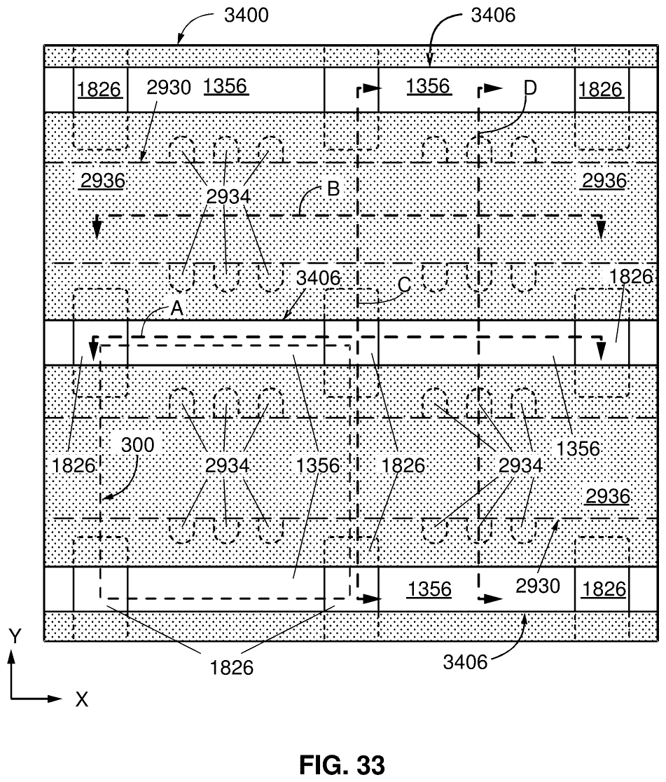

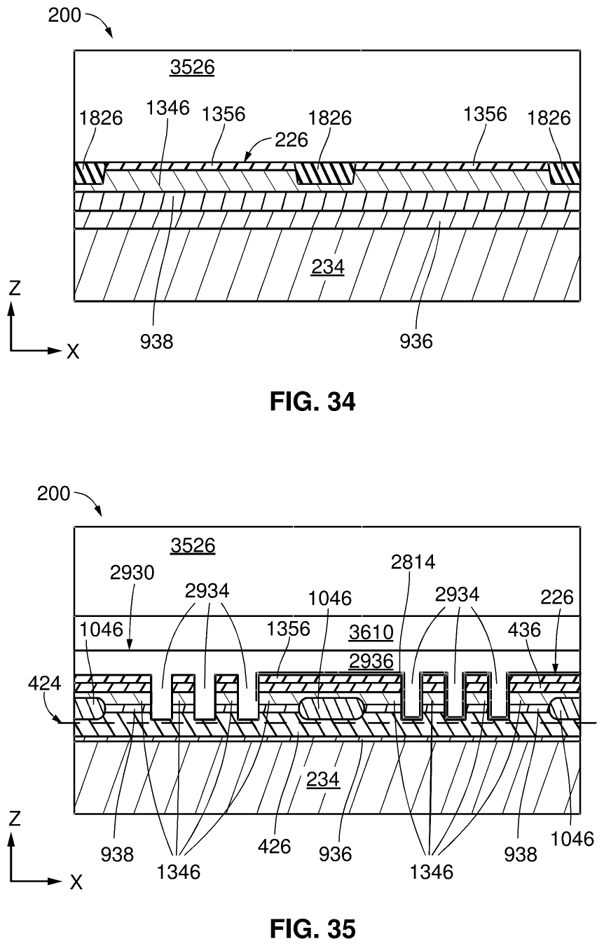

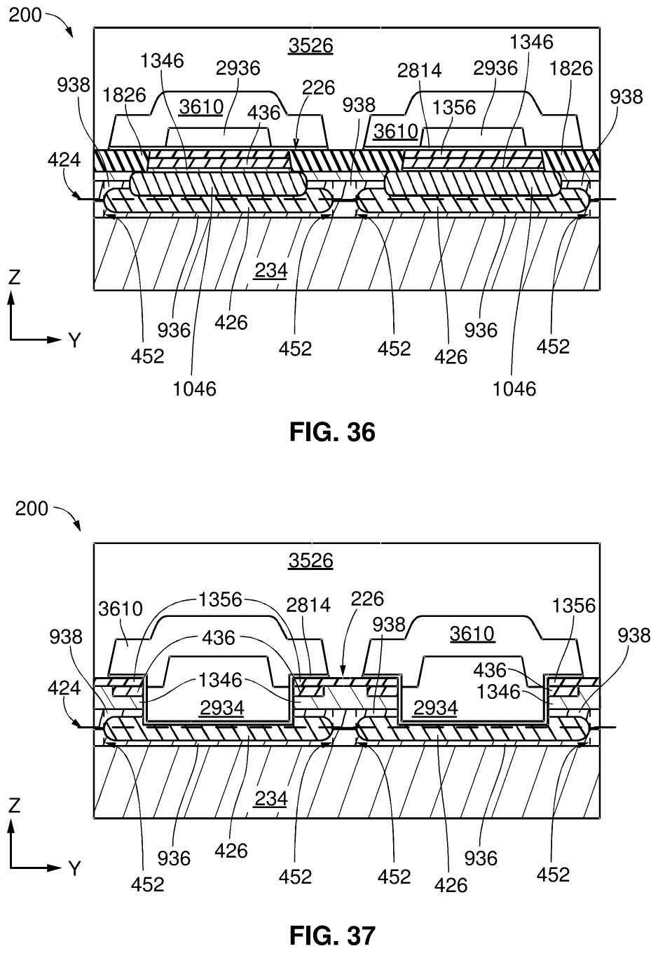

Referring to FIGS. 33 to 37, an interlevel dielectric (ILD) layer 3610 can be formed over the workpiece 200, and a contact mask 3400 can be formed over the ILD layer 3610 and include contact openings 3406. FIGS. 34 to 37 include cross-sectional views of the workpiece 200 after forming the source terminal 3526. FIG. 34 is along the sectioning line A in FIG. 33, FIG. 35 is along the sectioning line B in FIG. 33, FIG. 36 is along the sectioning line C in FIG. 33, and FIG. 37 is along the sectioning line D in FIG. 33.

The ILD layer 3610 can include a single film or a plurality of films. The single film or any one or more of the films within the plurality of films can include an oxide, a nitride, or an oxynitride. The single film or any one or more of the films within the plurality of films may or may not be doped with boron, phosphorus, or the like. The ILD layer 3610 can be deposited to a thickness in a range from 0.5 micron to 3.0 microns. A planarization process can be performed so that the uppermost surface of the ILD layer 3610 lies along a plane. The planarization process can be performed using chemical mechanical polishing or a resist etch-back process.

In FIG. 33, the contact mask 3400 defines the contact openings 3406 that expose portions of the ILD layer 3610. The contact mask 3400 can be made of photoresist. The contact openings 3406 overlap parts of the shallow portion 1356 of the source region and body contact regions 1826. In FIG. 33, some, and not all, of the body contact regions 1826 and portions of the shallow portion 1356 of the source region are labeled. The contact openings 3406 can be spaced apart from the gate members 2930. The contact mask 3400 can include other openings that expose portions (not illustrated in FIG. 33) of the gate members 2930, wherein such openings are located along the workpiece 200 at locations outside of the views as illustrated in FIGS. 33 to 37. The ILD layer 3610 is etched to expose parts of the shallow portion 1356 of the source region, the body contact regions 1826, and the gate members 2930. The contact mask 3400 is removed after the etch is performed.

A conductive layer is deposited over the ILD layer 3610 and within contact openings extending through the ILD layer 3610 to contact the shallow portion 1356 of the source region, the body contact regions 1826, and the gate members 2930. The conductive layer can include one or more films, wherein each film includes a conductive material. In an implementation, the conductive material can include a doped semiconductor material, an elemental metal (a metal that is not part of a compound or an alloy), a metal alloy, or a conductive metallic compound. A non-limiting example of a conductive material can be doped polysilicon (n-type or p-type), W, WN, Ti, Ta, TiW, Al-1 wt % Cu, Ni, Cu, Au, Pt, a conductive metal nitride (e.g., WN, TiN, TaN, etc.), a conductive metal silicide (NiSi, TiSi₂, CoSi₂, PtSi, etc.), or the like. In an implementation, the conductive layer can be deposited to a thickness in a range from 0.7 micron to 5.0 microns.

A photoresist mask is formed over the conductive layer, and the conductive layer is patterned to form a source terminal 3526 in FIGS. 34 to 37 and a gate terminal (not illustrated). The source terminal 3526 physically contacts the shallow portion 1356 of the source region and the body contact regions 1826. In an implementation, ohmic contacts are formed between the source terminal 3526 and the shallow portion 1356 of the source region and the body contact regions 1826. The gate terminal can physically contact the gate members 2930.

If needed or desired, a passivation layer (not illustrated) can be formed over the ILD layer 3610, the source terminal 3526, and the gate terminal. The passivation layer can include one or more films of an insulating material. In a particular implementation, the passivation layer includes polyimide that is coated and patterned to expose portions of the source terminal 3526 and the gate terminal. The reverse side of the workpiece may be provided with a metal layer that is a drain terminal and physically contacts the semiconductor base material 232.

FIG. 38 includes a cross-sectional view of portions of unit cells adjacent to one of the gap regions 452 to illustrate the majority carrier flow within the transistor structures. Portions of the workpiece above the major surface 226 are removed to improve understanding of features of the power transistor. Body contact regions 1826 and deep body regions 1046 are present but not seen in FIG. 38. The majority carrier flow is illustrated with the arrows. Majority carriers are electrons for an n-channel transistor and holes for a p-channel transistor.

In a finished device and when the power transistor is in an on-state, majority carriers flow along paths from the shallow portion 1356 and the deep portion 436 of the source region, through channel regions that are portions of the body region 1346 that are adjacent to the sidewalls of the gate trenches 2404, into the carrier accumulation region 938, into the carrier distribution layer 936 via the gap region 452, through the semiconductor layer 234, through the semiconductor base material 232 (not illustrated in FIG. 38), and into a drain terminal (not illustrated) for the power transistor.

The majority carriers flow substantially vertically (in the Z-direction) through the channel region and are illustrated in FIG. 38 with arrows extending through the body region 1346 and into the carrier accumulation region 938. After entering the carrier accumulation region 938, the majority carriers flow substantially laterally (in the X-direction) between the body region 1346 and the buried shield 426 and are illustrated in FIG. 38 with arrows within the carrier accumulation region 938. Although FIG. 38 includes arrows illustrated in the X-direction passing through the center of carrier accumulation region 938, the majority carriers are not restricted to flow only along the center of the carrier accumulation region 938. At least some of the majority carriers can flow through the carrier accumulation region 938 at locations other than in the center of the carrier accumulation region 938.

The majority carriers enter the gap region then flow substantially vertically (in the Z-direction) through gap region 452 and enter the carrier distribution layer 936. Although FIG. 38 includes a single arrow illustrated in the Z-direction passing through the center of gap region 452, the majority carriers are not restricted to flow only along the center of the gap region 452. At least some of the majority carriers can flow through the gap region 452 at locations other than in the center of the gap region 452.

The carrier distribution layer 936 helps to distribute more uniformly the majority carriers into semiconductor layer 234 as compared to transistor structures where the carrier distribution layer 936 would have been restricted only to the gap region 452 or where the carrier distribution layer 936 is replaced by the semiconductor layer 234 (the semiconductor layer 234 would have extended into the gap region 452 and physically contacted the carrier accumulation region 938).

After entering the carrier distribution layer 936, at least some of the majority carriers can flow substantially laterally (in the X-direction) under the buried shield 426 and are illustrated in FIG. 38 with a double-headed arrow extending within the carrier distribution layer 936. The majority carriers can then flow from the carrier distribution layer 936 into the semiconductor layer 234 and are illustrated with the vertical arrows (in the Z-direction) extending from the double-headed arrow within the carrier distribution layer 936 to the semiconductor layer 234. Although FIG. 38 includes the double-headed arrow illustrated in the X-direction passing through the center of carrier distribution layer 936, the majority carriers are not restricted to flow in the X-direction only along the center of the carrier distribution layer 936. At least some of the majority carriers can flow through the carrier distribution layer 936 at locations other than in the center of the carrier distribution layer 936. Referring to FIG. 38, the majority carrier flow from the carrier distribution layer 936 into the semiconductor layer 234 is illustrated with relatively thinner arrows in the Z-direction. The majority carriers can flow in a substantially vertical direction within the semiconductor layer 234 and the semiconductor base material 232 (not illustrated in FIG. 38).

In FIG. 38, the deep portion 436 of the source region does not overlap the gap region 452 and are laterally spaced apart from the gap region 452. The shallow portion 1356 of the source region extends across all of the width of the gap region 452 as illustrated in FIG. 38. The body region 1346 is locally thicker over the gap region 452 as compared to the channel regions of the transistor structures at the gate trenches 2404. The combination of shallow and deep portions 1356 and 436 of the source region as illustrated in FIG. 38 allows for acceptable low source contact resistance and a relatively higher drain-to-source punch through voltage because the body region 1346 is thicker over the gap region 452. If the deep portion 436 of the source region would have extended across all of the gap region 452, the power transistor would have relatively lower drain-to-source punch through voltage.

Many different benefits may be seen in different implementations of the concepts described herein. The implementations have at least one benefit described herein but not all benefits are required to be seen in all implementations.

Deep body regions 1046 can allow for lower resistance between the source terminal 3526 and the buried shield 426 as compared to the deep body regions 1046 not being present. The lower resistance allows the buried shield 426 to have a potential closer to the source voltage, V_{S}. The deep body regions 1046 can be spaced apart from the gap regions 452, and thus the R_{SP} is not adversely affected by the deep body regions 1046. The deep body regions 1046 obviate the need for deep body contact regions that would be aligned to the body contact regions 1826. Such deep body contact regions would extend through and reduce the area of the gap regions 452 and adversely affect R_{SP}.

P-type dopant can be a metal element having an atomic number of at least 13. If a sufficient amount of the p-type dopant accumulates with the gate dielectric layer 2814, the gate dielectric layer 2814 may fail. To improve long-term gate dielectric reliability, p-type regions and layers having relatively high peak dopant concentrations, such as the body contact regions 1826 and the deep body regions 1046, can be spaced apart from the gate members 2930 by a minimum distance. The high peak dopant concentration of these regions reduces the resistance to the buried shield 426 below what would be possible if the dopant concentration of these regions had to be reduced in order to maintain gate dielectric reliability. The minimum distance can be a fixed distance or may be a function of the peak dopant concentration of a particular p-type doped region or layer. When the peak dopant concentration is below a threshold concentration, a minimum distance may not be needed.

Many different aspects and implementations are possible. Some of those aspects and implementations are described below. After reading this specification, skilled artisans will appreciate that those aspects and implementations are only illustrative and do not limit the scope of the inventive concepts. Implementations may be in accordance with any one or more of the implementations as listed below.

Implementation 1. An electronic device can include a substrate defining a gate trench that has a sidewall and extends to a gate trench depth from a major surface of the substrate, wherein the substrate includes a semiconductor layer having a first conductivity type. The electronic device can further include a body region having a second conductivity type opposite the first conductivity type; a body contact region having the second conductivity type; a buried shield having the second conductivity type and a peak dopant concentration, wherein the buried shield underlaps the gate trench; a deep body region having the second conductivity type and a peak dopant concentration, wherein the peak dopant concentration of the deep body region is greater than the peak dopant concentration of the buried shield; a gate dielectric layer within the gate trench; and a gate member including a portion extending into the gate trench. In a direction perpendicular to the major surface, the deep body region can be located between the body region and the buried shield, the body region can be along a portion of the sidewall of the gate trench and spaced apart from the gate member by the gate dielectric layer. The gate member may not overlap the body contact region, and the gate member can overlap and be spaced apart from the deep body region by the body region.

Implementation 2. The electronic device of Implementation 1, wherein each of the body contact region and the deep body region includes a dopant that is a metal element having an atomic number of at least 13.

Implementation 3. The electronic device of Implementation 2, wherein the semiconductor layer is a SiC layer.

Implementation 4. The electronic device of Implementation 1 further includes a gap region having the first conductivity type and defined at least in part by the buried shield.

Implementation 5. The electronic device of Implementation 4 further includes a carrier accumulation region having the first conductivity type, wherein the carrier accumulation region extends across all of the gap region and is located between the body region and the buried shield.

Implementation 6. The electronic device of Implementation 5 further includes a carrier distribution layer having the first conductivity type, wherein the gap region includes portions of the carrier distribution layer and the carrier accumulation region.

Implementation 7. The electronic device of Implementation 6, wherein the buried shield overlaps the carrier distribution layer.

Implementation 8. An electronic device can include a substrate defining a gate trench that extends to a gate trench depth from a major surface of the substrate, wherein the substrate includes a semiconductor layer having a first conductivity type. The electronic device can further include a body contact region having a second conductivity type opposite the first conductivity type; a buried shield having the second conductivity type and a peak dopant concentration, wherein the buried shield underlaps the gate trench; a gap region having the first conductivity type, wherein the gap region is defined at least in part by the buried shield; and a deep body region having the second conductivity type and a peak dopant concentration. The body contact region, the buried shield, and the deep body region can be electrically coupled to one another, the deep body region may not overlap all of the gap region, the deep body region can be spaced apart from the major surface of the substrate, and the peak dopant concentration of the deep body region can be greater than the peak dopant concentration of the buried shield.

Implementation 9. The electronic device of Implementation 8 further includes a body region having the second conductivity type and lying along a sidewall of the gate trench; a gate dielectric layer within the gate trench, wherein the gate dielectric layer has a thickness; and a gate member that includes a portion extending into the gate trench. The gate member is spaced apart from the body region by the gate dielectric layer, the body contact region by a body contact distance that is greater than the thickness of the gate dielectric layer, and the deep body region by a deep body distance that is greater than the thickness of the gate dielectric layer.

Implementation 10. The electronic device of Implementation 9 further includes a source region having the first conductivity type, wherein, along a direction perpendicular to the major surface, the gate dielectric layer, the source region, and the body region are disposed between the deep body region and the gate member.

Implementation 11. The electronic device of Implementation 10, wherein the source region includes a shallow portion and a deep portion, wherein the shallow portion overlaps the gap region, and the deep portion does not overlap the gap region.

Implementation 12. The electronic device of Implementation 8, wherein, from a plan view, the deep body region has a length and a width, wherein the length is greater than the width, and the length of the deep body region lies along a first line, the gap region has a length and a width, wherein the length is greater than the width, and the length of the gap region lies along a second line. The first line intersects the second line at an angle that is 90°+/−5°.

Implementation 13. A process of forming an electronic device can include determining a minimum distance between a gate member and a doped region within a compound semiconductor material, wherein the doped region has a dopant that is a metal element having an atomic number of at least 13, and the doped region has a peak dopant concentration of at least 5×10¹⁸ atoms/cm³. The process can further include forming a buried shield within a compound semiconductor layer of a substrate, wherein the compound semiconductor layer has a first conductivity type, and the buried shield has a second conductivity type opposite the first conductivity type; forming a body region within the compound semiconductor layer, wherein the body region has the second conductivity type, and a peak dopant concentration less than 5×10¹⁸ atoms/cm³; forming a body contact region within the compound semiconductor layer, wherein the body contact region has the second conductivity type and a peak dopant concentration of at least 5×10¹⁸ atoms/cm³, and the body contact region is electrically coupled to the buried shield; patterning the substrate to define a gate trench that has a sidewall and extends to a gate trench depth from a major surface of the substrate; and forming a gate member including a portion extending into the gate trench. The gate member can be spaced apart from the body region by a body distance that is less than the minimum distance, and the body contact region by a body contact distance that is at least the minimum distance.

Implementation 14. The process of Implementation 13 further includes forming a deep body region having the second conductivity type and a peak dopant concentration of at least 5×10¹⁸ atoms/cm³. The gate member is spaced apart from the deep body region by a deep body distance that is at least the minimum distance.

Implementation 15. The process of Implementation 13 further includes forming a deep body region within the compound semiconductor layer, wherein the deep body region has the second conductivity type and a peak dopant concentration of at least 5×10¹⁸ atoms/cm³. In a direction perpendicular to the major surface, the body region is located between the deep body region and the major surface, the gate member overlaps the deep body region, and the gate member is spaced apart from the deep body region by a deep body distance that is at least the minimum distance.

Implementation 16. The process of Implementation 15, wherein the buried shield at least in part defines a gap region having the first conductivity type, and the deep body region is spaced apart from and does not overlap and does not extend into the gap region.

Implementation 17. The process of Implementation 13 further includes forming a current accumulation region having the first conductivity type. The buried shield has a peak dopant concentration less than 5×10¹⁸ atoms/cm³, is spaced apart from the body region by the current accumulation region, and is spaced apart from the gate member by less than the minimum distance.

Implementation 18. The process of Implementation 13, wherein determining the minimum distance is performed such that the minimum distance is a function of a peak dopant concentration of the doped region.

Implementation 19. The process of Implementation 18, wherein the minimum distance is a first distance for the peak dopant concentration having a first value and a second distance for the peak dopant concentration having a second value, wherein the first distance is different from the second distance, and the first value is different from the second value.

Implementation 20. The process of Implementation 13, wherein determining the minimum distance includes a horizontal component along the major surface and a vertical component in a direction perpendicular to the major surface.

Implementation 21. The process of Implementation 20, wherein the horizonal component is different from the vertical component.

Implementation 22. The process of Implementation 20 or 21, wherein the horizonal component is the same as the vertical component.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific implementations. However, the benefits, advantages, solutions to problems, and any feature(s) that may cause any benefit, advantage, or solution to occur or become more pronounced are not to be construed as a critical, required, or essential feature of any or all the claims.

The specification and illustrations of the implementations described herein are intended to provide a general understanding of the structure of the various implementations. The specification and illustrations are not intended to serve as an exhaustive and comprehensive description of all of the elements and features of apparatus and systems that use the structures or methods described herein. Separate implementations may also be provided in combination in a single implementation, and conversely, various features that are, for brevity, described in the context of a single implementation, may also be provided separately or in any subcombination. Further, reference to values stated in ranges includes each and every value within that range. Many other implementations may be apparent to skilled artisans only after reading this specification. Other implementations may be used and derived from the disclosure, such that a structural substitution, logical substitution, or another change may be made without departing from the scope of the disclosure. Accordingly, the disclosure is to be regarded as illustrative rather than restrictive.

What is claimed is:

1. An electronic device, comprising:
a substrate defining a gate trench that has a sidewall and extends to a gate trench depth from a major surface of the substrate, wherein the substrate includes a semiconductor layer having a first conductivity type;
a body region having a second conductivity type opposite the first conductivity type;
a body contact region having the second conductivity type;
a buried shield having the second conductivity type and a peak dopant concentration, wherein the buried shield underlaps the gate trench;
a deep body region having the second conductivity type and a peak dopant concentration, wherein the peak dopant concentration of the deep body region is greater than the peak dopant concentration of the buried shield;
a gate dielectric layer within the gate trench; and
a gate member including a portion extending into the gate trench,
wherein:
in a direction perpendicular to the major surface, the deep body region is located between the body region and the buried shield,
the body region is along a portion of the sidewall of the gate trench and is spaced apart from the gate member by the gate dielectric layer,
the gate member does not overlap the body contact region, and
the gate member overlaps and is spaced apart from the deep body region by the body region.

2. The electronic device of claim 1, wherein each of the body contact region and the deep body region includes a dopant that is a metal element having an atomic number of at least 13.

3. The electronic device of claim 2, wherein the semiconductor layer is a SiC layer.

4. The electronic device of claim 1, further comprising:
a gap region having the first conductivity type and defined at least in part by the buried shield.

5. The electronic device of claim 4, further comprising:
a carrier accumulation region having the first conductivity type, wherein the carrier accumulation region extends across all of the gap region and is located between the body region and the buried shield.

6. The electronic device of claim 5, further comprising:
a carrier distribution layer having the first conductivity type, wherein the gap region includes portions of the carrier distribution layer and the carrier accumulation region.

7. The electronic device of claim 6, wherein the buried shield overlaps the carrier distribution layer.

8. An electronic device, comprising:
a substrate defining a gate trench that extends to a gate trench depth from a major surface of the substrate, wherein the substrate includes a semiconductor layer having a first conductivity type;
a body contact region having a second conductivity type opposite the first conductivity type;
a buried shield having the second conductivity type and a peak dopant concentration, wherein the buried shield underlaps the gate trench;
a gap region having the first conductivity type, wherein the gap region is defined at least in part by the buried shield; and
a deep body region having the second conductivity type and a peak dopant concentration, wherein:
the body contact region, the buried shield, and the deep body region are electrically coupled to one another,
the deep body region does not overlap all of the gap region,
the deep body region is spaced apart from the major surface of the substrate, and
the peak dopant concentration of the deep body region is greater than the peak dopant concentration of the buried shield.

9. The electronic device of claim 8, further comprising:
a body region having the second conductivity type and lying along a sidewall of the gate trench;
a gate dielectric layer within the gate trench, wherein the gate dielectric layer has a thickness; and
a gate member that includes a portion extending into the gate trench, wherein the gate member is spaced apart from:
the body region by the gate dielectric layer,
the body contact region by a body contact distance that is greater than the thickness of the gate dielectric layer, and
the deep body region by a deep body distance that is greater than the thickness of the gate dielectric layer.

10. The electronic device of claim 9, further comprising
a source region having the first conductivity type, wherein, along a direction perpendicular to the major surface, the gate dielectric layer, the source region, and the body region are disposed between the deep body region and the gate member.

11. The electronic device of claim 10, wherein the source region comprises a shallow portion and a deep portion, wherein the shallow portion overlaps the gap region, and the deep portion does not overlap the gap region.

12. The electronic device of claim 8, wherein, from a plan view:
the deep body region has a length and a width, wherein the length is greater than the width, and the length of the deep body region lies along a first line,
the gap region has a length and a width, wherein the length is greater than the width, and the length of the gap region lies along a second line, and
the first line intersects the second line at an angle that is 90°+/−5°.

13. A process of forming an electronic device, comprising:
determining a minimum distance between a gate member and a doped region within a compound semiconductor material, wherein:
the doped region has a dopant that is a metal element having an atomic number of at least 13, and
the doped region has a peak dopant concentration of at least 5×10¹⁸ atoms/cm³;
forming a buried shield within a compound semiconductor layer of a substrate, wherein the compound semiconductor layer has a first conductivity type, and the buried shield has a second conductivity type opposite the first conductivity type;
forming a body region within the compound semiconductor layer, wherein the body region has the second conductivity type, and a peak dopant concentration less than 5×10¹⁸ atoms/cm³;
forming a body contact region within the compound semiconductor layer, wherein the body contact region has the second conductivity type and a peak dopant concentration of at least 5×10¹⁸ atoms/cm³, and the body contact region is electrically coupled to the buried shield;
patterning the substrate to define a gate trench that has a sidewall and extends to a gate trench depth from a major surface of the substrate; and
forming a gate member including a portion extending into the gate trench, wherein the gate member is spaced apart from:
the body region by a body distance that is less than the minimum distance, and
the body contact region by a body contact distance that is at least the minimum distance.

14. The process of claim 13, further comprising:
forming a deep body region having the second conductivity type and a peak dopant concentration of at least 5×10¹⁸ atoms/cm³, wherein:
the gate member is spaced apart from the deep body region by a deep body distance that is at least the minimum distance.

15. The process of claim 13, further comprising:
forming a deep body region within the compound semiconductor layer, wherein the deep body region has the second conductivity type and a peak dopant concentration of at least 5×10¹⁸ atoms/cm³, wherein:
in a direction perpendicular to the major surface, the body region is located between the deep body region and the major surface,
the gate member overlaps the deep body region, and
the gate member is spaced apart from the deep body region by a deep body distance that is at least the minimum distance.

16. The process of claim 15, wherein the buried shield at least in part defines a gap region having the first conductivity type, and the deep body region is spaced apart from and does not overlap and does not extend into the gap region.

17. The process of claim 13, further comprising:
forming a current accumulation region having the first conductivity type, wherein the buried shield:
has a peak dopant concentration less than 5×10¹⁸ atoms/cm³,
is spaced apart from the body region by the current accumulation region, and
is spaced apart from the gate member by less than the minimum distance.

18. The process of claim 13, wherein determining the minimum distance is performed such that the minimum distance is a function of a peak dopant concentration of the doped region.

19. The process of claim 18, wherein the minimum distance is a first distance for the peak dopant concentration having a first value and a second distance for the peak dopant concentration having a second value, wherein the first distance is different from the second distance, and the first value is different from the second value.

20. The process of claim 13, wherein determining the minimum distance comprises a horizontal component along the major surface and a vertical component in a direction perpendicular to the major surface.
